(19) United States
(12) Patent Application Publication
(10) Pub. No.: US 2022/0130344 A1
(43) Pub. Date: Apr. 28, 2022

(54) EFFICIENT IMAGE DATA DELIVERY FOR AN ARRAY OF PIXEL MEMORY CELLS

(71) Applicant: Jasper Display Corp., Grand Cayman (KY)

(72) Inventors: Bo Li, Santa Clara, CA (US); Kaushik Sheth, Santa Clara, CA (US); Edwin Lyle Hudson, Santa Clara, CA (US)

(21) Appl. No.: 17/568,831

(22) Filed: Jan. 5, 2022

Related U.S. Application Data
(63) Continuation-in-part of application No. 17/354,419, filed on Jun. 22, 2021.
(60) Provisional application No. 63/045,252, filed on Jun. 29, 2020.

(51) Int. Cl. G09G 3/36; G11C 11/419; G11C 11/418; G11C 11/412

(52) U.S. Cl. CPC G09G 3/3648; G11C 11/419; G11C 11/418; G09G 2300/0871; G09G 2300/0842; G09G 2310/08; G11C 11/412

(57) ABSTRACT

A backplane design for delivering image data in an efficient manner to a memory cell forming a part of a pixel drive circuit comprises a word line design and a column data register release signal delivery design that are speed matched and a complementary bit line delivery design that is speed matched to a row decoder signal circuit operative to pull a word line driver to a state to enable the memory circuits of that row to receive data from the column drivers for each column. The speed matching is effective over a range of operating temperatures because the circuit designs are substantially identical.

### CROSS REFERENCE TO RELATED APPLICATIONS

The present application is a Continuation-in-Part of U.S. patent application Ser. No. 17/354,419, “Large Backplane Suitable for High Speed Applications,” filed on Jun. 22,2021, which claims the benefit of U.S. Provisional Patent Application Ser. No. 63/045,252, filed on Jun. 29, 2020.

### FIELD OF THE INVENTION

The present invention relates to the efficient delivery of image data to a pixel memory cell in the form of a single bit of data corresponding to a bit plane required to establish a modulation state for the duration of the bit plane. More particularly, this relates to the delivery of image data to the pixels of a pulse width modulated display.

### BACKGROUND OF THE INVENTION

The use of semiconductor backplanes as a component for spatial light modulators is well known in the art. Microdisplays used to generate images to be observed by human viewers have been offered for sale for over 20 years and are well attested to in the published and patent literature. Later applications have emerged in telecommunications devices wherein a phase aligned spatial light modulator can be used to steer a coherent beam of light to a desired location through use of a suitable kinoform (phase mask) implemented by modulating a liquid crystal layer. The backplane technology used for both classes of devices are often identical. Large format liquid crystal on silicon microdisplays are of particular value. They are found in projection systems for business meeting support as well as in projectors for digital cinema. A large-format phase aligned spatial light modulator (SLM) based on the same silicon design may be used to expand the number of incoming beams that can be steered to different outgoing ports in a telecommunications router.

Liquid crystal on silicon devices have been implemented using silicon backplane designs based on memory devices. In an early example, Dr. Timothy Drabik discloses in his doctoral thesis Optically Interconnected Parallel Processor Arrays, (Georgia Institute of Technology, Atlanta, Ga., December 1989) (hereafter Drabik 1989), on page 125, the use of an SRAM as the basis of a pulse-width modulated 64 by 64 liquid crystal array, commonly referred to as a liquid crystal on silicon, or LCOS, device. Drabik 1989 identifies that the SRAM may be written either by using byte-wide operation wherein a byte of data comprising 8 bits may be written to 8 memory cells of the selected row or else by using row-page mode wherein all eight bytes on a row comprising 64 memory cells may be written when the selected row line (wordline) is held high. Those of ordinary skill in the art of electronic design will recognize that the byte-wide mode requires that the individual columns be addressable whereas the row-page mode does not specifically require that capability although row-page mode is certainly compatible with that means of addressing data to columns.

In another point regarding Drabik 1989, the thesis on that same page notes two specific aspects of the SRAM as implemented intended to increase operating speed. The first is the row-page mode previously described because it reduces the number of times the wordline of the row must be pulled high from 8 to 1. The second is the addition of an inverter circuit to isolate the 6-transistor SRAM circuit of each pixel from load coming from the pixel mirror. Drabik 1989 reports that this allows the hold time required to set the state of the SRAM circuit to be reduced from a few microseconds (μsec) to a few nanoseconds (nsec). Applicant notes that efforts to decrease the time required to accomplish necessary actions such as the writing of data have been ongoing since the earliest days of liquid crystal on silicon displays and spatial light modulators.

Applicant has previously developed a backplane with an aspect ratio of 4096 by 2400 (a 128 by 75 ratio), comprised of square pixels with a pitch of 3.74 micrometers (μm) in both horizontal and vertical directions. The target process for this development is a 130 nanometer (nm) process using copper circuits and transistors underneath aluminum pixel mirrors with an optional interposing layer to prevent unwanted interactions between two dissimilar metal layers. The pixel mirrors act not only to reflect light but are driven by a voltage supplied by the underlying circuits that corresponds to a desired modulation. The image diagonal of the array of the backplane is 0.70 inches (0.70″). One limitation of this choice of resolution and process is that the maximum voltage range spread for the pixel mirrors is approximately 4 volts. A spread of 5 volts or more is far more desirable, especially for phase-aligned devices where the liquid crystal cell must be thicker because the required phase modulation range is at least double that required for an amplitude-aligned display. This voltage limitation results from the library of transistors available within the process selected and the need to keep the pixel circuit area within an area approximately equal to the square of the pixel pitch. Additionally, the height of a row driver and the width of a column driver must conform to the pixel pitch for that dimension.

Applicant currently holds U.S. Pat. No. 7,443,374, the entire contents whereof are incorporated by reference, that discloses a pixel circuit design comprising a 6 transistor SRAM and other elements that has been implemented in a 250-nm process, a 180-nm process and a 130-nm process. (See particularly, FIGS. 5-8, including the correction to FIG. 6.)

Other pixel circuits exist that may receive the benefits of the present invention. For example, the pixel circuit described in U.S. Pat. No. 6,005,558, the entire contents whereof are incorporated herein by reference, also relies on a one-bit SRAM memory cell to establish a modulation state for the pixel circuits. The pixel circuit of U.S. Pat. No. 6,005,558 and the pixel circuit of U.S. Pat. No. 7,443,374 have approximately the same effect on an associated liquid crystal layer but accomplish this through means that are otherwise substantially dissimilar. Other pixel circuits relying on one-bit SRAM or DRAM devices may benefit from the present invention.

In the present application, the terms wire, conductor and line are presumed to mean a conductive medium, such as aluminum, copper, or polysilicon, although other conductive mediums are within the scope of the present disclosure. The use of the word terminal means a conductive medium operative to connect to a node of a circuit element, such as a logic gate or a source, gate or drain of a transistor, or to the bulk of a semiconductor. The terms word line, wordline and WLINE are all used by practitioners in the art and are to be considered equivalent to one another. The terms row driver and wordline driver shall be considered to be equivalent to one another. The terms bit line, bitline and column line shall be considered to be equivalent to one another. The terms column driver and bitline driver shall be considered to be equivalent to one another.

### SUMMARY OF THE PRESENT INVENTION

It is therefore an object of the present invention to improve on a backplane forming a part of a display system by reducing the time required to load a plane of data to the pixel circuits of that backplane. In particular, a device design in which the setup and hold time requirement may be reduced relative to other designs will enable the writing of data to the storage element of each pixel cell more rapidly and also enable the entire array to be written more rapidly. This will mean a higher overall data rate than would otherwise be possible.

### BRIEF DESCRIPTION OF THE DRAWINGS

FIG. 1A presents a functional block diagram of the backplane of a spatial light modulator.

FIG. 1B presents an electrical schematic of an SRAM memory cell.

FIG. 1C presents a functional block diagram of a portion of a row decoder circuit operative to activate a wordline of a selected row of an SRAM memory.

FIG. 1D presents a function block diagram of a column driver circuit operative to configure the complementary bitlines of a column of an SRAM memory.

FIG. 2A presents a plan view of the memory cells of an SRAM memory annotated with depictions of propagation delay.

FIG. 2B presents a 2 by 2 block of pixels illustrating path length differences.

FIG. 3 presents an equivalent circuit of the resistance and capacitance of a segment of a conductor in a semiconductor.

FIG. 4A depicts a block diagram of a set of row release segments of a display operative to provide a release signal to the AND gates of the row drivers of that set.

FIG. 4B depicts a block diagram of a single row release segment of a display operative to provide a release signal to the AND gates of the row drivers of that segment.

FIG. 4C depicts a simplified block diagram of a pair of bitlines forming part of an array of dummy pixels together with column drivers and a trigger circuit controller.

FIG. 4D depicts a detailed block diagram of one tap circuit operative to deliver a release trigger signal to a plurality of AND gates.

FIG. 5A depicts a block diagram of a set of column release segments of a display operative to provide a release signal to a circuit element of the column drivers of that set.

FIG. 5B depicts a block diagram of a single column release segment of a display operative to provide a release signal to a circuit element of the column drivers of that segment.

FIG. 5C depicts a diagram of the wordlines and other circuit elements of a dummy array of pixels operative to send a trigger pulse to a bitline driver to release stored data onto the bitlines.

FIG. 5D depicts a diagram of a section of a circuit operative to receive a trigger pulse delivered over a dummy wordline and deliver it to a column driver to release data stored on the column driver onto the bitlines of that column.

FIG. 6A is a block diagram of an arrangement of word lines on a backplane divided into four vertical sections each modulated by a different display controller.

FIG. 6B is a block diagram of the right side of the block diagram of FIG. 6A with added detail.

FIG. 6C is a block diagram of a 2×2 array of pixel drive circuits in which even rows and odd rows are modulated independently of each other.

FIG. 6D presents an equivalent circuit of the resistance and capacitance of a segment of a conductor in a semiconductor wherein the resistance and capacitance of a first part of the segment differs from the resistance and capacitance of a second part of the segment.

FIG. 7A is a block diagram of the left half of an array of pixel drive circuits comprising two vertical sections of pixel drive elements modulated by separate display controllers.

FIG. 7B is an illustration of time delays for delivery of data to the memory elements of a pixel drive circuit.

FIG. 7C is an illustration of time delays in a section of a display located further from its bit line drivers than other sections.

### DETAILED DESCRIPTION OF THE INVENTION

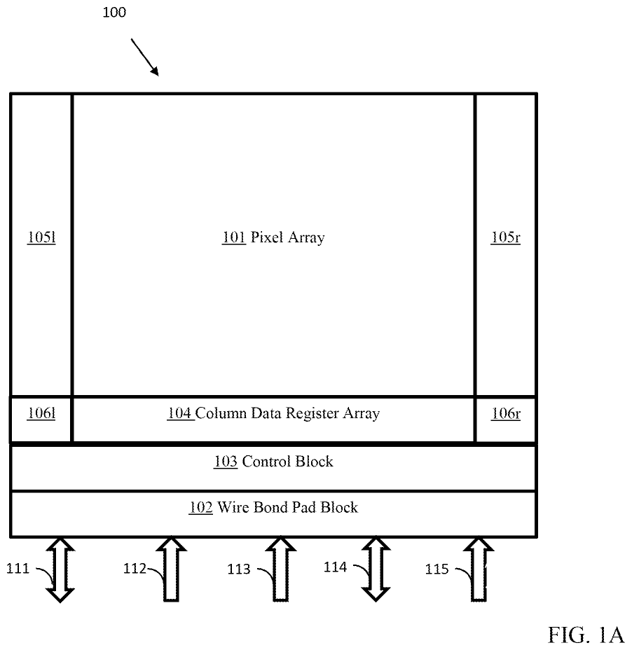

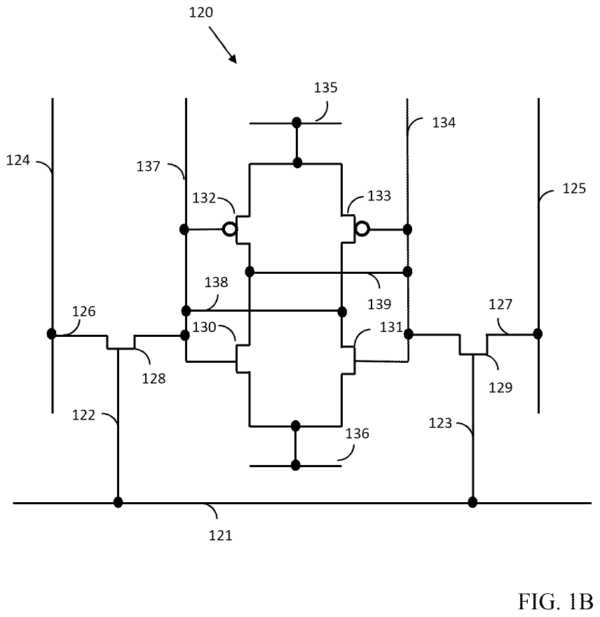

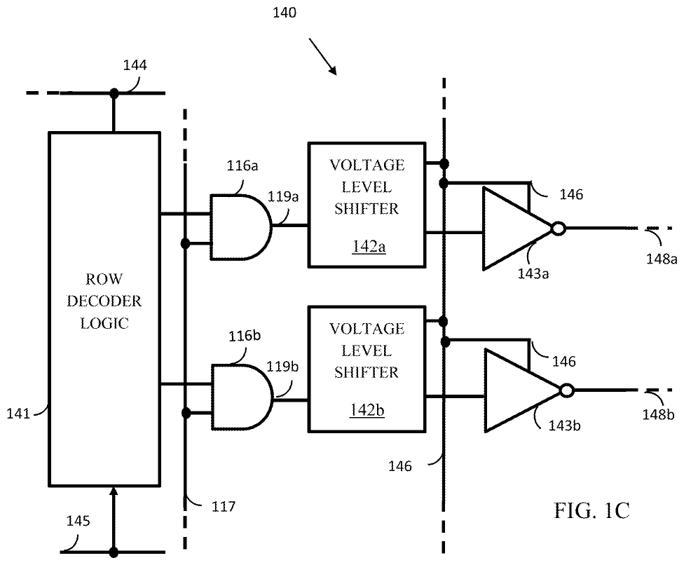

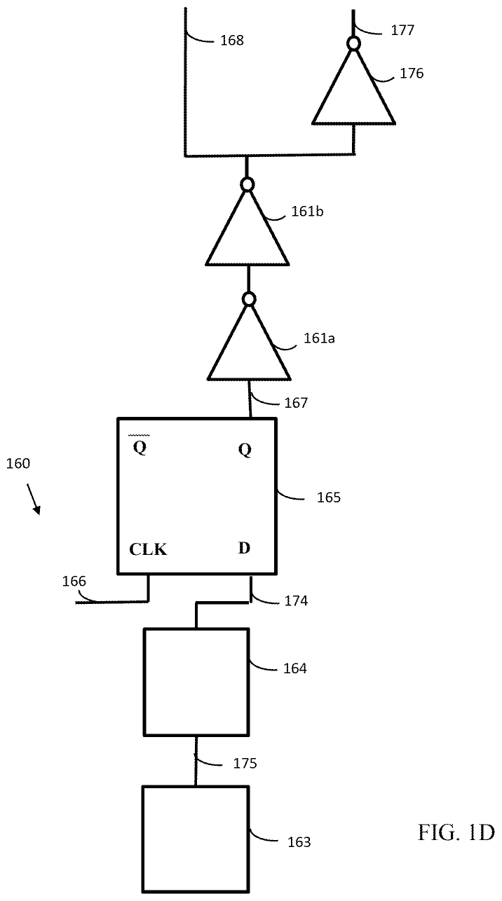

FIG. 1A presents a functional block diagram comprising the data transfer sections of spatial light modulator (SLM) 100. SLM 100 comprises pixel array 101, left row decoder and driver assembly 105l, right row decoder and driver assembly 105r, left write signal control section 106l, right signal control section 106r, column data register array 104, control block 103, and wire bond pad block 102. Wire bond pad block 102 is configured so as to enable contact with an FPCA (flexible printed circuit assembly) or other suitable connecting means so as to receive data and control signals over lines from an SLM controller (not shown). The data and control signal lines comprise clock signal line 111, op code signal lines 112, serial input-output signal lines 113, bidirectional temperature signal lines 114, and parallel data signal lines 115.

Bidirectional clock signal line 111 provides a clock signal from an external control device (not shown) operative to deliver data to the SLM in coordination with the clock. In one embodiment, both rising edge and falling edge clock edges are used.

Serial input-output lines 113 provide data from an external control device (not shown) operative to configure the SLM to a required operating condition. Bidirectional temperature signal lines 114 provide data from an external control source (not shown) to configure a temperature measurement circuit (not shown) within the SLM to a desired operating condition and to transmit information from the temperature measurement circuit to the external control source.

Wire bond pad block 102 receives image data and control signals and moves these signals to control block 103. Control block 103 receives the image data and routes the image data to column data register array 104. Row address information is routed to row decoder left 105l and to row decoder right 105r. In one embodiment, only one row decoder is used for the entire array. In one embodiment, the value of Op Code line 112 determines whether data received on parallel data signal lines 115 is address information indicating the row to which data is to be loaded or data to be loaded to a row. In one embodiment the row address information acts as header, appearing first in a time ordered sequence, to be followed by data for that row. In the context of the present application, the word “address” is most often a noun used to convey the location of the row to be written. The location may be conveyed as an offset from the location (address) of a baseline row or it may be an absolute location of the row to be written. This is similar to the manner in which a Random-Access Memory device, such as an SRAM, is written or read. The use of column addressing, also used in Random-Access Memory devices, may be envisioned, but other mechanisms, such as a shift register, are also envisioned. Use of a shift register to enable the writing of data to rows of the array is also envisioned.

Row decoder and driver assembly left 105l and row decoder and driver assembly right 105r comprise a set of circuits operative to pull a wordline for the decoded row high using a row driver circuit (not shown) so that data for that row may be transferred from column data register array 104 to the storage elements resident in the pixel cells of the selected row of pixel array 101. In one embodiment, row decoder and driver assembly left 105l applies a signal operative to pull the wordline high for a left half of the display, and row decoder and driver assembly right 105r pulls the wordline high for a right half of the display. In one embodiment, the output of the row decoder. In one embodiment, the circuits of row decoder and driver assemblies 105l and 105r comprise an AND gate on each row (not shown) operative to receive a signal from a row decoder circuit and a trigger signal from a circuit (not shown) operative to deliver the trigger signal to all AND gates of all rows. Only the AND gate of the selected row receives two high signals and delivers a high signal output. In one embodiment, row decoder and driver assemblies 105l and 105r comprise a voltage level shift circuit.

Block 106l and block 106r represent trigger release circuits operative to deliver a trigger signal to pull the wordline high on the selected row and a separate trigger signal to release the data stored on the memory cell of the bitline driver onto the complementary bitlines for each pixel of the selected row. In one embodiment, the signal from trigger release circuits 106l and 106r forms one input to an AND gate (not shown) which has as a second input a signal from row decoder logic block 105l and 105r. This gives greater temporal control over the timing of pulling the wordline high. Trigger release circuits 106l and 106r may also be though of as release timing circuits.

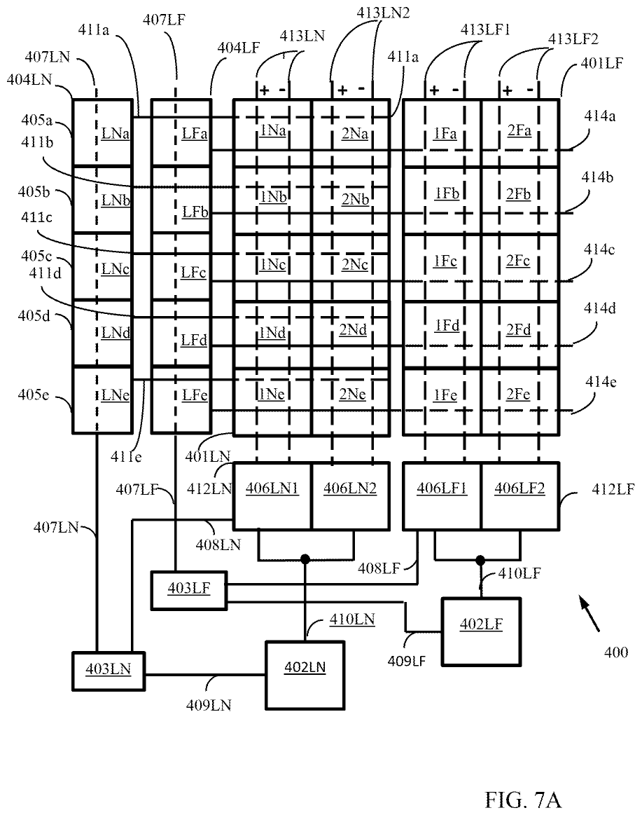

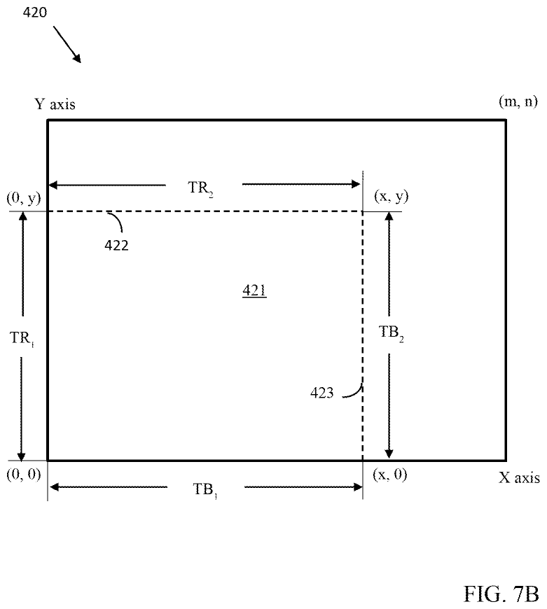

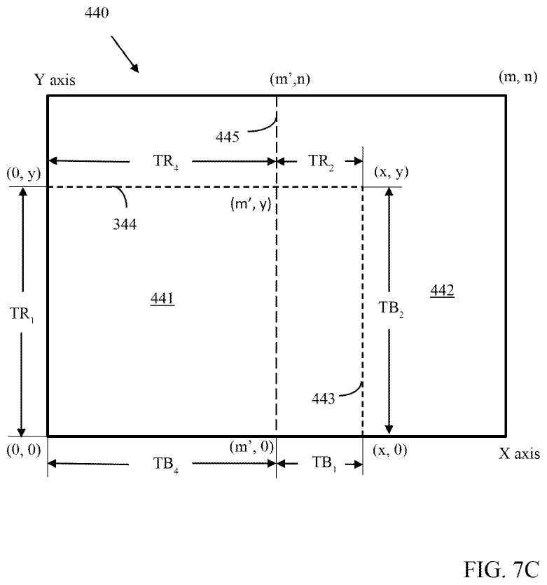

FIG. 1B shows a preferred embodiment of a data storage element 120 that forms part of a pixel element. Data storage element 120 is preferably a CMOS static ram (SRAM) latch device. Such devices are well known in the art. See DeWitt U. Ong, Modern MOS Technology, Processes, Devices, & Design, 1984, Chapter 9, Section 5, (hereafter Ong 1984) the details of which are hereby fully incorporated by reference into the present application. See also Drabik 1989, previously cited, FIG. 7.11, page 126. A static RAM is one in which the data is retained as long as power is applied, though no clocks are running. FIG. 1B shows the most common implementation of an SRAM memory cell in which six transistors are used. MOSFET transistors 128, 129, 130, and 131 are n-channel transistors, while MOSFET transistors 132, and 133 are p-channel transistors. In this particular design, wordline 121, when held high, applies voltage to the gates of pass transistors 128 and 129 over terminal 122 and 123 respectively, allowing (B_{POS}) 124, and (B_{NEG}) 125 lines to remain at a pre-charged high state or be discharged to a low state by the flip flop (i.e., transistors 132, 133, 130, and 131). Differential sensing of the state of the flip-flop is then possible in read mode. In writing data into the selected cell, (B_{POS}) 124 and (B_{NEG}) 125 are forced high or low by additional write circuitry comprising a column driver circuit (not shown). The side that goes to a low value is the one most effective in causing the flip-flop to change state. Data on B_{POS} 124 is asserted onto the source of pass transistor 128 over terminal 126 and data on B_{NEG} 125 is asserted onto the source of pass transistor 129 over terminal 127. The gate voltage applied to transistors 131 and 133 over conductor 134 is asserted onto the drain of transistor and source of transistor 130 over conductor 139. The gate voltage applied to transistors 130 and 132 over conductor 137 is applied to the drain of transistor 133 and the source of transistor 131 over conductor 138. In one embodiment of the present application, two output ports 134 and 137 are required to relay to circuitry in the remainder of the pixel circuit whether the data state of the SRAM is in an “on” state or an “off” state. In some embodiments, only one output port is required. Lines (B_{POS}) 124 and (B_{NEG}) 125 are also commonly referred to as bit lines or bitlines.

SRAM circuit 120 is connected to V_{DDAR} at bus 135 and to V_{SS} at bus 136. V_{DDAR} denotes the V_{DD} for the array. It is common practice to use lower voltage transistors for periphery circuits such as the I/O circuits and control logic of a backplane for a variety of reasons, including the reduction of EMI and the reduced circuit size that this makes possible. Other voltage difference may be implemented for a variety of reasons too numerous to state succinctly.

The six-transistor SRAM cell is desired in CMOS type design and manufacturing since it involves the least amount of detailed circuit design and process knowledge and is the safest with respect to noise and other effects that may be hard to estimate before silicon is available. In addition, current processes are dense enough to allow large static RAM arrays. These types of storage elements are therefore desirable in the design and manufacture of liquid crystal on silicon display devices as described herein. However, other types of static RAM cells are contemplated by the present invention, such as a four transistor RAM cell using a NOR gate, as well as using dynamic RAM cells rather than static RAM cells.

The convention in looking at the output ports of an SRAM is to term the outputs as complementary signals S_pos or S_{POS} and S_neg or S_{NEG}. The output of memory cell 120 is shown as connecting the gate of transistors 133 and 131 over conductor 134. By convention this side of the SRAM is normally referred as S_{NEG}. The gates of transistors 132 and 130, connected over conductor 137, are normally referred to as S_{POS}. Either side can be used to provide a data source. In the case of U.S. Pat. No. 7,443,374, previous cited, both sides are used with additional circuitry to select one or the other of the two outputs depending on DC balance state.

FIG. 1C presents a block schematic of row driver assembly 140 of a device comprising a plurality of rows of SRAM memory cells (not shown) or similar memory cell each forming part of a pixel drive circuit. Row drivers for DRAM circuits are similar to row driver 140. A row driver may also be referred to as a word line driver. Depicted row driver circuit 140 is presented as driving two rows. Many additional rows are conceived. In one product, applicant has 2464 rows each with an individual row driver. Row driver 140 comprises row decoder logic 141, AND gates 116a and 116b, voltage level shifters 142a and 142b, and inverters 143a and 143b. Row decoder logic 141 is operative to select a single row of all of the rows of an array of SRAM memory cells such as array 101 of FIG. 1A based on address information provided to the backplane. In one embodiment address information identifying a row to which data is to be written is provided in conjunction with the data to be written to that row.

Row decoder logic 141 may be one of several types of row decoders as are well known in the art of Random Access Memories (RAM) design. Row decoder logic 141 is connected to a voltage source (not shown) over conductor 144. The voltage source may be set to V_{DD} or to a different voltage source V_{DD_I0} or to a third type of voltage source V_{DD-RD} as selected by the designer. In one embodiment, the voltage source of row selector is lower than the voltage source present within the pixel array. Row decoder 141 is connected to V_{SS} over conductor 145. It is common practice for a common V_{SS} to be used across sections of a device with differing V_{DD} voltages in different circuit sections.

As a general rule, a row decoder is limited to four NAND gates because, if more NAND gates are used, the resultant circuit becomes electrically complex and unacceptably slow. To achieve the required functionality over a large number of rows, the decoding is separated into predecoders that in turn provide inputs into a series of decoder circuits. As this is well known and attested to, it is not repeated here. See, for example, VLSI-Design of Non-Volatile Memories, G. Campardo, et al, pages 185-188, especially the bottom of page 187, Springer Verlag, Berlin et al, 2005, (hereafter Campardo 2005).

Row decoder logic 141 is operative to provide a voltage as an input to AND gate 116a and to AND gate 116b and to all other rows out of the totality of rows of the SRAM. Only one AND gate receives a high voltage from the row decoder circuit, indicating that that row is the selected row. All AND gates, whether 116a, 116b or another AND gate not shown here, are also connected by trigger gate line 117 to a trigger source (not shown). When trigger gate line 117 receives a high voltage, indicating a trigger, that voltage is applied to all AND gates. Only the AND gate of the selected row fully satisfies the AND gate logic requirement and delivers an on-state voltage to its output. The addition of the AND gate reduces any uncertainty as to be timing of the triggering of the WordLine (WLINE). In one embodiment, AND gates 116a, 116b, and all other AND gates (not shown) comprise a pair of pass transistors in series.

In one embodiment, AND gates 116a and 116b are replaced by logic circuits after logic circuit 165 of column driver 160 of FIG. 1D. Logic circuit 165 may be either a level sensitive D flip-flop or an edge sensitive D latch. The AND gate, the D flip-flop and the D latch are all types of logic circuits. Appropriate inverters, voltage level shifters and other minor circuits (not shown) may be needed to reach the required voltage polarity and voltage level.

In one embodiment the output of AND gate 116a is connected to voltage level shifter 142a over terminal 119a. The output of AND gate 116b is connected to voltage level shifter 142b over terminal 119b. In like manner each of the remaining AND gates is connected to a voltage level shifter over a voltage conducting means, such as a terminal, conductor or wire. The use of a voltage level shifter is preferred when a section of a device, such as an array of memory cells operative to drive an array of pixels requires specific voltage ranges which may differ from the input-output circuits or the periphery.

Voltage level shifter 142a receives a signal from AND gate 116a over terminal 119a, and voltage level shift 142b receives a signal from AND gate 116b over terminal 119b. Each of all other voltage level shifters (not shown) receives a signal from its respective AND gate over a terminal. All these signals are 0 except for the signal from the one selected row. Voltage level shifters 142a, 142b and all other voltage level shifters (not shown) associated with row drivers are connected to a V_{DD_WL} (V_{DD} WordLine) source over conductor 146. The outputs of voltage level shifters 142a and 142b are connected to inverters 143a and 143b respectively. The outputs of all other voltage level shifters (not shown) that form part of row drivers are in like manner connected to inverters. The output of inverter 143a is asserted on conductor 148a and the output of inverter 143b is asserted on conductor 148b. All other inverters (not shown) are likewise asserted onto conductors and onto feedback conductors. In one embodiment, conductor 148a, conductor 148b, and all other conductors driven in a similar manner are wordlines (WLINE) of an array of pixel drive circuits.

In one embodiment for each row driver, the voltage level shifter comprises a p-channel transistor configured with its source connected to voltage supply V_{DD_WL} and its drain connected to the output of the AND gate. In that same embodiment, each inverter comprises a p-channel transistor in series with an n− channel transistor wherein the inputs to each transistor is a signal from the AND gate of the row driver to the gates of both transistors and wherein the source of the p-channel transistor is connected to V_{DD_WL} and the drain of the n-channel transistor is connected to ground (V_{SS}). The output of the inverter is connected to the wordline and to the gate of the p-channel transistor of the voltage level shifter (not shown). A detailed explanation of voltage shifters and their use in row drivers is found on pages 184-187 of Campardo 2005 (previously cited). Voltage level shifter designs operative to shift voltages down as well as up are within the scope of this invention.

In one embodiment, the output of the level shifter is held to a voltage lower than the voltage V_{DD_AR} (V_{DD_ARRAY}). Operating the word line below its maximum possible voltage provides an effective means of lowering the overall current of the array and thereby any residual heating that may result. This may require that the pass transistors for the memory circuits, similar to pass transistors 128 and 129 of SRAM circuit 120 (FIG. 1B), of the array of pixel drive circuits be adapted to conduct when that voltage is applied to their gates.

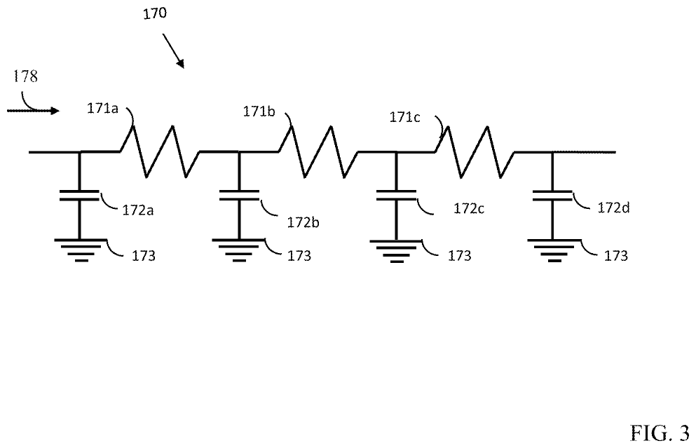

Capacitance on the wordline (WLINE) places a strong burden on the design of a row driver. Inverters 143a and 143b serve to buffer each row driver of row driver assembly 140 from the effects of the high capacitance load. The nature of the capacitance on the wordline is explained in more detail for FIG. 3.

FIG. 1D presents column driver 160. Column driver 160 comprises memory cell 163 operative to store a bit of data, optional voltage level shifter 164 operative to shift a periphery voltage to a bitline voltage, and logic circuit 165 operative to receive a data voltage and assert complementary output voltages through intermediary circuits onto data output terminals 168 and 177 responsive to a data clock signal asserted onto terminal CLK 166. In one embodiment, the data clock signal asserted onto terminal CLK 166 is a trigger signal sent from a trigger control circuit on the backplane (not shown). Alternate names for clock CLK are release REL and enable EN.

Memory cell 163 receives and stores a bit of image data for a plane of image data from an external source. The stored data is asserted on terminal 175 which asserts that data value onto voltage level converter 164. Voltage level converter 164 asserts the converted data voltage level onto terminal 174 which asserts that data voltage onto data terminal D of logic circuit 165. In one embodiment, voltage shifter circuit 164 is replaced with a straight through conductor. In one embodiment, logic circuit 165 is a circuit with two stable states. The voltage asserted on data terminal D is asserted onto Q and its complement onto terminal Q. The voltage asserted onto terminal Q is asserted onto output terminal 167. Terminal Q is not used. Output terminal 167 in turn asserts the value of terminal Q onto inverter 161a. The output of inverter 161a is asserted onto the input of inverter 161b. The output of inverter 161b holds the same logic value as the input to inverter 161a. Together inverters 161a and 161b form a buffer operative to isolate column driver 160 from capacitive loading present on the complementary bitlines. The output of inverter 161b is asserted onto bitline 168 and onto the input to inverter 176. The output of inverter 176 is asserted onto bitline 177, which logically forms a complementary bitline pair with bitline 168.

Logic circuit 165 enables system level control over the timing of the release of image data onto the bitlines of the driven column of an array of active pixels. Several types of circuits provide the functionality required. Two circuits that are particularly suitable are the D latch and the D flip-flop. (The letter D in the two circuit names may denote either Data or Delay. Both names are indicative of features of the same circuit.) Not all sources make a distinction between latch and flip-flop. In this application, a distinction between a D latch and a D flip-flop is maintained.

A D latch is a level sensitive circuit with nodes comprising a data input node D, a clock node CLK, and output nodes Q and Q. When CLK is high, the data asserted on D is the data value asserted on Q and its complement is asserted on Q. If the data asserted on D changes while CLK is high, then the values asserted on Q and Q also change.

In contrast, a D flip-flop is a clock edge sensitive circuit. The input and output nodes are the same as for the D latch; however, the performance differs in that when a rising clock edge is detected, the data value asserted on input D is asserted onto Q and its complement is asserted on Q. If the data value asserted on input D subsequently changes, the outputs asserted onto Q and Q do not change until another rising clock edge is detected. A falling clock edge does not affect the output; however, there are similar circuits that trigger on a falling clock edge and not on a rising clock edge. For this application, the clock edge to enable the circuit is assumed to be a rising edge subject to the understanding that alternative implementations fall within the scope of this disclosure. For further reference, 14-Flip-flops.pdf, author unknown, Class Presentation for CSE370, Lecture 14, University of Washington, 2008, pages 2-5 provides useful information.

In one embodiment, logic circuit 165 may be replaced with an AND gate such as AND gates 116a or 116b of word line driver assembly 140 of FIG. 1C. The operation of the AND gate is similar to the operation of the D latch version as described for logic circuit 165. In fact, both are logic circuits as is the D flip-flop previously described. Appropriate inverters, voltage level shifters and other minor circuits (not shown) may be needed to reach the required voltage polarity and voltage level.

One issue that arises frequently in the design of an array is propagation delay, also known as path propagation delay. As previously noted, applicant has developed arrays with more than 9.8 million pixels (4096×2400). The intersection of each row with each column represents two unique paths.

A first path is the row select path combined with the wordline for a row, referred to as the wordline path hereafter. Several types of circuits are known that allow a single row of a memory device to be selected. In many cases, the row is designated by an address location that causes a row decoder circuit to select that particular row before a signal is sent to the row to pull the wordline high. The output of a row decoder circuit enters an AND gate that also is configured to receive a separate trigger signal delivered to all AND gates able to receive the output of the row decoder circuits. The wordline itself forms the second part of the row select path, comprising the physical distance from the row driver along the wordline to the pixel of interest. All trigger signal generating circuits may function as release timing circuits.

A second path is the bitline path. The bitline path comprises a data load trigger path that delivers a voltage to a circuit in the bitline driver that releases the data stored on the bitline driver to the array of the display and the complementary bitlines to the pixel.

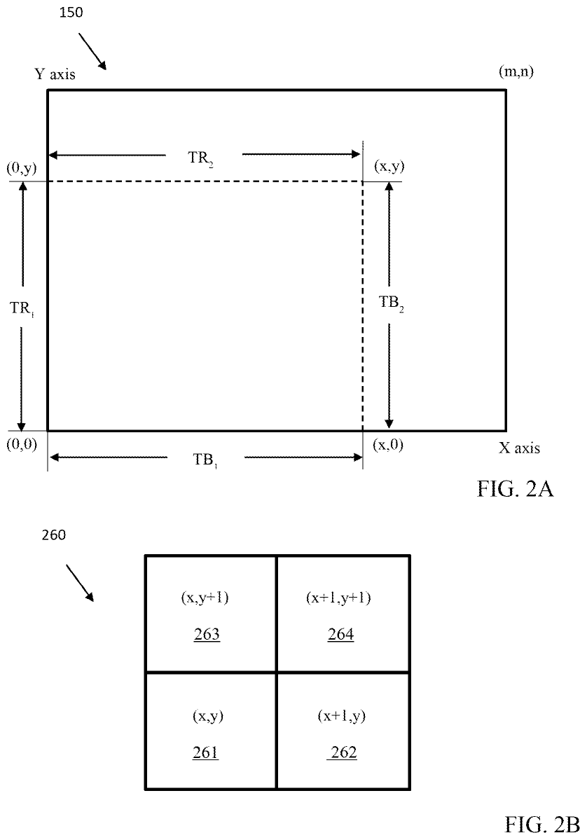

In FIG. 2A, an SRAM array 150 that is m columns wide by n rows high is presented for discussion of propagation delay. For this example, a trigger signal for the release of image data onto the bitlines and a trigger signal to activate circuitry associated with the row drivers to pull the wordline high are presumed to originate in circuitry proximate to coordinates (0, 0) in the lower left-hand corner of the array. It is understood that triggers signals may originate in more than one location. For example, one location may be proximate to the lower left corner of the pixel array and a second location may be proximate to the lower right corner of the pixel array, and wherein the lower left trigger location may handle the left half of the array and the lower right trigger location may handle the right half of the array.

Considering the wordline path above, the time from when the trigger signal is sent from coordinates adjacent to coordinate (0, 0) to the AND gate until the trigger signal arrives at the AND gate adjacent to coordinate (0, y) is depicted as TR₁. TR₁ represents the time required for the trigger signal to propagate from the point adjacent to coordinate (0, 0) to coordinate (0, y). The use of distance to represent time is appropriate because the propagation delay along that path has a uniform characteristic when the circuits carrying a signal on that part of the path are uniform and repetitive. The second part of the path is the wordline. The wordline for an array of SRAM type memory cells is connected to the gates of pass transistors such as transistors 128 and 129 of SRAM circuit 120 of FIG. 1B. The resistance of the wordline conductor and the capacitance of the wordline and of the connections to the pass transistors define the RC characteristic of the wordline and therefore the propagation delay of the wordline. The RC characteristic of the wordline may differ from the RC characteristic of the line on which the trigger signal used as an input to the AND gate at each row driver propagates.

In the case wherein the pixel pitch in the x direction is a uniform X distance units laterally across the display and the pixel pitch in the y direction is a uniform Y distance units vertically on the display, pixel location (x, y) is at a physical position relative to the origin at (0, 0) of X distance units times x laterally and Y distance units times y vertically. The choice of distance unit is arbitrary, although most modern pixels are specified in microns, or millionths of a meter from center to center.

The same considerations can be applied to other display geometries such as a parallelogram provide the opposite sides are of equal length and parallel, such as a rhomboid. It can also be applied in modified form to a display with a pixel format that is anamorphic on one of its principal axes. The principle difference is that the pixel pitch on that axis is not uniform, requiring use of other types of calculations for distance, such as a lookup table.

There are other delays inherent in logic components such as the AND gates, voltage level shifters, and inverters such as those of row driver circuit 140 of FIG. 1C. These delays are of uniform character for each row and do not vary from row to row, making them predictable in that all pixels of all rows have the same delay from that source inherent upon them.

The time from when the trigger signal to the column driver to release complementary data onto the bitlines is initiated and its arrival at the column drive and the time from the release of data from the column drivers until the data arrives at the pixel of interest (x, y) in the array together require a variable amount of time, wherein that variation depends mainly on the path lengths of the two segments and the individual RC (resistance and capacitance) characteristics of the circuits forming the two segments along which this propagates.

The path that brings the trigger signal from the trigger initiating circuit to the column driver extends from coordinates (0, 0) to (x, 0) along the X-axis of array 150. The time required for the signal to propagate that distance is designated as TB₁. The duration of TB₁ is determined by the RC characteristic of the conductor over which the trigger signal propagates. The RC characteristic is in turn determined by the physical characteristics of the conductor, which comprise resistive and capacitive coupling components and the physical characteristics of any transistor nodes along the path, which primarily comprise capacitive coupling components. This may be thought of as a network. The actual voltage of the trigger signal does not affect the RC characteristic of a network.

The second part of the path that delivers bitline data to the pixel of interest is initiated when the bitline data is released from the column driver circuit. There are inherent delays within the column driver circuits that are identical for all columns. The propagation delay from the time the data is released onto the bitlines for the pixel of interest until the data arrives at the pixel of interest on the selected row depends on the distance from the column driver to the pixel of interest in addition to the bitline characteristics, namely the RC delay. For analysis, the time delay is noted as TB₂. TB₂ is the time required for the bitline data to propagate from coordinate (x, 0) to coordinate (x, y) of the pixel of interest. The additional delay due to various logic circuits can be lumped together as TB₃ (not shown) and treated as a constant value not dependent on the pixel position. The total delay TB_{TOT} (not shown) due to propagation delay from the trigger source to the pixel of interest is TB_{TOT}=TB₁+TB₂+TB₃.

The wordline path begins with the path from a second trigger initiation that delivers the trigger signal up the side of the display from coordinate (0,0) to coordinate (0,y). The actual path is slightly outside the array but is parallel to the Y-axis as depicted. The time required for the trigger signal to propagate along this first path is TR1. The duration of TR1 is, as before, determined by the RC characteristic of the line over which the trigger pulse propagates to reach the row driver at coordinate (0,y). The second part of the wordline path is the wordline itself. The wordline on the selected row is pulled high when the trigger signal reaches the AND gate which forms part of the row driver circuit. The propagation time, TR₂, is determined by the RC characteristics of the wordline. The additional delay due to various logic circuits can be lumped together as TR₃ (not shown) and treated as a constant value not dependent on the pixel position. The total delay TR_{TOT} (not shown) due to propagation delay from the trigger source to the pixel of interest is defined as TR_{TOT}=TR₁+TR₂+TR₃.

An observation based on the calculations for FIG. 2A is that the physical length associated with the path for TB₁ added to the length of the path TB₂ is substantially equal to the physical length associated with the path for TR₁ added to the length of the path for TR₂. Another evident characteristic is that the physical length associated with TR₁ is substantially equal to the physical length associated with TB₂ and the physical length associated with TR2 is substantially equal to the physical length associated with TB₁.

Note that the RC characteristic associated with the path for TR₁ does not necessarily match the RC characteristic associated with the path for TR₂, and that the RC characteristic associated with the path for TB₁ does not need to match the RC characteristic associated with the path for TB₂. If both the RC characteristic and the physical length associated with a first circuit are substantially equal to the RC characteristic and physical length associated with a second circuit, then the propagation delay along the two circuits will be substantially equal.

Based on the observation above that the physical path length associated with TR₁ is substantially equal to the physical path length associated with TB₂, it follows that the propagation delays associated with the two physical paths can yield similar propagation delays if the RC characteristics of the two physical paths are substantially the same. The same consideration regarding RC characteristics applies to the case of the path length associated with TR₂ and the path length associated with TB₁. The difficulty lies in identifying means by which the entire length of the circuit carrying the trigger signal to the row decoder can be RC matched to the bitlines acting as circuits to carry data to the pixels of the selected row.

This and a similar consideration for RC matching between the path length associated with the trigger signal to the column driver and the wordline from the row decoder to the pixel of interest (x, y) is addressed in the present application. Stated in other terms, it is important that the equation TR₁+TR₂=TB₁+TB₂ is substantially satisfied. The design procedures disclosed in the present application support achieving that result.

RC matching is the subject of significant development effort in the design of semiconductor devices. Much of the work is devoted to design techniques and practices that reduce the effects of any mismatches in RC matching. While useful for many pure memory designs, techniques such as dividing the wordline into many sub wordlines are less useful in the field of displays based on memory devices at each pixel when the goal is to write an entire line of data to the display as rapidly as possible rather than to write a single word to a portion of a row.

FIG. 2B depicts a 2 by 2 block of pixels 260 comprising pixel (x, y) 261, pixel (x+1, y) 262, pixel (x, y+1) 263 and (x+1, y+1) 264, that form a part of array of pixels 150 in FIG. 2A. The depiction emphasizes that the length of the paths to each pixel differs in some way. Using pixel 261 at coordinate (x, y) as a base, pixel 262 is on the same row as pixel 261 but one pixel further away from a row driver (not shown) on the left edge of the array. Pixel 263 is located one row directly above pixel 261 which increases the distance from a column driver (not shown) at the base of the array of pixels. Pixel 264 is located on the row above pixel 261 and one pixel further from the left edge of the array of pixels. While pixel 262 and pixel 263, depicted as square pixels, may appear to have the same path length, other pixel aspect ratios are possible. In one embodiment, the pixels may be rectilinear but not square (not shown). In this case the pixel circuit and row and column drivers will all need to fit into the respective row and column spacings. In one embodiment the pixels may be hexagonal (not shown). In a hexagonal array the pixels of adjoining rows are typically offset one half column from one another although the underlying pixel circuits may be rectilinear.

FIG. 3 presents equivalent circuit 170 for the resistance and capacitance characteristics of a segment of a conductor forming part of a semiconductor, based on a circuit in previously cited Campardo 2005, FIG. 9-10, page 183. Resistors 171a, 171b, and 171c each represent a portion of the resistance on the segments of equivalent circuit 170. For a conductor of resistance R, the distributed resistance values for resistors 171a, 171b and 171c are each R/3. Arrow 178 indicates the direction of current flow.51a51a5 is well known that the resistance of a conductor is proportional to its length and inversely proportional to its cross section. Each type of conductor has a resistivity ρ, specified in Ω-m (ohm meters). The resistivity of aluminum at 20° C. is 2.7×10⁻⁸ Ω-m and the resistivity of copper at the same temperature is 1.7×10⁻⁸ Ω-m. The formula to calculate resistance R in ohms (Ω) for the above calculation is R=ρL/A where L is the length of the conductor and A is the cross-section area of the conductor. The metric more commonly used is the sheet resistance given in R_{□}. The three dimensions of a conductor in a VLSI semiconductor are nominally L length, W width and H height. H height is the thickness of the conductor layer on top of the layer below. The cross-section area is A=W×H. In most processes H height is a constant value and can divided into ρ to created R_{□}=ρ/H, referred to as resistance per square.

Capacitors 172a, 172b, 172c and 172d, each connected to common ground 173, represent distributed capacitance within the conductor represented by equivalent circuit 170. For equivalent circuit 170 with net capacitance C, the capacitance for capacitors 172b and 172c are considered to be C/3, The capacitance for end capacitors 172a and 172d are considered to be C/(2*3) or C/6. Arrow 270 indicates the direction of propagation for a signal on the conductor.

In general, a conductor may be represented as an equivalent circuit comprising n resistive elements and n+1 capacitive elements. The resistance of each resistor is R/n and the capacitance of all capacitive elements 2 to n is considered to equal C/n. The capacitance of equivalent capacitors 1 and n+1 is considered to equal C/2n.

Capacitance in a conductor within a semiconductor has several components that contribute to the total capacitance. One component is referred to as area capacitance is based on a parallel plate model wherein conductors on different levels of a semiconductor are separated by a dielectric medium. Another component is referred to as fringing field capacitance. It's significance results from the reduction in W width of a conductor to the point where its H height is greater than W width in newer processes with finer design rules. The topic is complex and the subject of a significant amount of advanced research. A reference is Digital Integrated Circuits, A Design Perspective, 2^{nd} Ed., Rabaey, et al, Pearson Education, Delhi, 2002, pages 136-138, (hereafter Rabaey 2002.), the entire contents whereof are incorporated herein by reference.

An additional source of capacitance on a conductor is its interconnections to other circuit elements such as the various connections to a transistor. An example is found in lecture notes, Static Random Access Memory—SRAM, Dr. Lynn Fuller, Nov. 18, 2016, Rochester Institute of Technology, pages 12-13, (hereafter Fuller 2016) the entire contents whereof are incorporated by reference. Lecture notes Fuller 2016 identify that the wordline of the SRAM receive a contribution to total capacitance through the two pass transistors connected to it at each memory cell, such as pass transistors 128 and 129 of FIG. 1B of the present application, wherein the wordline is connected to the gates of those transistors. The exact nature of the connections a conductor makes to other components directly affects the C capacitance on that conductor and therefor the propagation delay associated with that conductor.

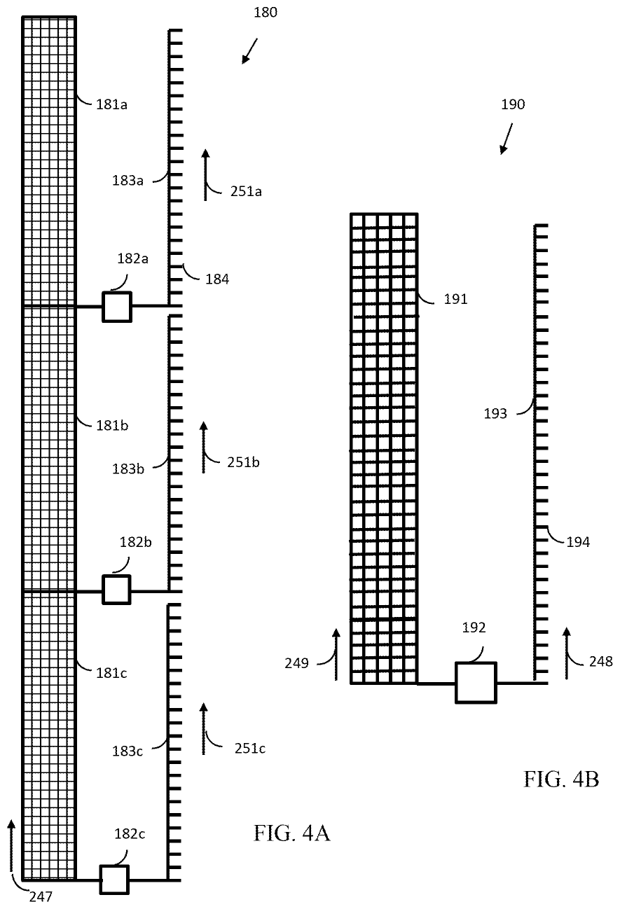

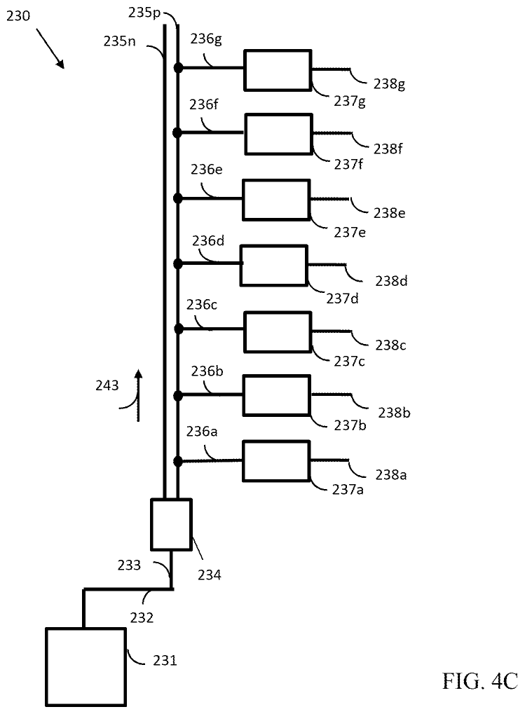

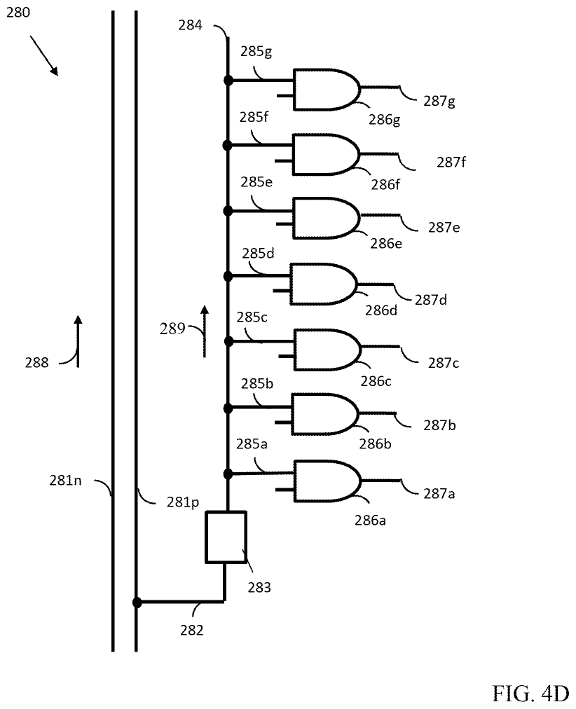

FIG. 4A depicts release signal delivery circuit 180 operative to deliver release signals to the AND gate of a row driver such as AND gates 116a and 116b of row driver circuit 140 presented in FIG. 1C in the present application. Release signal delivery circuit 180 comprises arrays of dummy pixels 181a, 181b and 181c, sample circuits 182a, 182b and 182c, also known as sense circuits, and conductor terminals 183a, 183b and 183c. Modeling in CAD design tools has revealed that it is preferable that the entire pixel circuit be duplicated in the dummy pixels in order to match the C capacitance contributed by the active pixel circuits of the array of pixels to the bitlines and wordlines.

Arrays of dummy pixels 181a, 181b and 181c each comprise a plurality of dummy pixel circuits, each identical to the active pixel circuits of the array of pixels with interconnections such as wordlines and bitlines (not shown) identical to the active pixel circuits of the array of pixels. Sample circuits 182a, 182b and 182c are not found on the active pixel circuits of the array of pixels. Sample circuits 182a, 182b and 182c detect a rising edge of a trigger signal on one of the bitlines (not shown) of dummy pixels 181a, 181b and 181c. Sample circuits 182a, 182b and 182c comprise a rising edge detector circuit and a circuit operative to hold the output signal high for a period of time after the rising edge on the sampled bitline is detected. An alternative name is a sense circuit. The main requirement is that the rising edge detection circuit be able to turn on again when the next rising edge is detected but not remain on the entire time from one rising edge to the next. In one embodiment, sense circuits 182a, 182b and 182c also detect the level of the trigger signal and turn the output of each sense circuit to off when the level of the trigger signal falls below a certain level. The output of sense circuits 182a, 182b and 182c are asserted onto conductors 183a, 183b and 183c respectively. Conductors 183a, 183b and 183c each connect to a plurality of AND gates (not shown) each forming part of a row driver circuit such as AND gates 116a and 116b of FIG. 1C at a plurality of terminals such as terminal 184 (one depicted). Arrow 247 indicates the direction of propagation of the release signal in array of dummy pixel segments 181a, 181b and 181c. Arrow 251c indicates the direction of propagation within conductor 183c, arrow 251b indicates the direction of propagation within conductor 183b, and arrow 251a indicates the direction of propagation within conductor 183a. A trigger signal source originates in other circuitry (not shown) located below release signal delivery circuit 180.

Array of dummy pixels 181a, 181b and 181c operate as a continuous unit. A trigger signal on one of the bitlines of segment of dummy pixel array 181c propagates from bottom to top, then continues to propagate on one of the bitlines of dummy pixel array 181b and then propagates on one of the bitlines of dummy pixel array 181a. The bitlines (not shown) of array of dummy pixels segments 181a, 181b and 181c form a continuous conductor with no circuitry or breaks intervening between segments 181a, 181b and 181c within the individual bitlines. The bitlines do connect to the gates of pass transistors (not shown) such as pass transistors 128 and 129 of SRAM circuit 120 shown in FIG. 1C. In addition, at relatively regular intervals a tap (not shown) on one of the bitlines asserts the value on that bitline (not shown) onto the input to a sense circuit such as sense circuits 182a, 182b and 182c.

FIG. 4B depicts segment 190 of a release signal delivery circuit representing one segment of a row release signal circuit similar to release signal delivery circuit 180 of FIG. 4A. Segment 190 comprises array of dummy pixels 191, sense circuit 192, also known as a sample circuit, conductor 193 and a plurality of terminals 194 (one indicated) to connect conductor 193 to the same number of AND gates forming part of a same number of row driver circuits (not shown) similar to row driver circuit 140 of FIG. 1C. Preferably the array of dummy pixels is colinear with the array of regular pixels (not shown). Arrow 249 indicates the direction of propagation of the release trigger signal within dummy pixel array segment 191. Arrow 248 indicates the direction of propagation of the release sign asserted by circuit element 192 onto conductor 193.

The structure of segment 190 is important. The direction of propagation of the release trigger signal within dummy pixel array segment 190 starts at the bottom and proceeds up as indicated by arrow 249. Sense circuit 192 samples the state of the trigger release signal within dummy pixel array 191 and releases a pulse onto conductor 193 corresponding to the state of the trigger release signal. The trigger signal propagates through bitlines (not shown) of dummy pixel array 191 at a velocity determined by the RC characteristics of the bitline and the capacitance of the circuit elements attached to it. The output of circuit element 192 propagates onto conductor 193 at a velocity corresponding to the RC characteristics of conductor 193 and the capacitance of the circuit elements (AND gates) attached to it. The length of dummy pixel array 191 and conductor 193 are almost identical, with the only difference arising because there needs to be a gap between a conductor and the next conductor, such as is the case for conductors 183a and 183b of FIG. 4A.

In the case where the pixels, whether dummy or active, are 6.4 μm by 6.4 the length of a conductor attached to 32 AND gates is W_{length}=6.4 μm×31=198.4 μm=0.1984 mm. The length of the bitline extending across 32 pixels is B_{length}=6.4 μm×32=204.8 μm=0.2048 mm. The difference is not significant since the trigger generated by the sense circuit does not need to propagate beyond the row driver for the uppermost row on that conductor. The differences in RC characteristics between the bitline over that distance and the conductor over a similar difference to drive 32 row drivers may result in a difference of less than 0.1%. Because a limited number of rows are driven from each tap and the tapped bitline runs parallel to the conductor, according to simulation, the discrepancy between propagation delay in the bitline (not shown) in array of dummy pixels 191 and propagation delay in conductor 193 is not cumulative.

FIG. 4C depicts bitlines and column driver circuit 230 of an array of dummy pixels comprising bitline pair 235p and 235n. Pixel circuit elements other than the bitlines are omitted for clarity. Trigger signal control and generating circuit 231 controls trigger pulse timing and generation, asserting the trigger pulse onto conductor 232. Conductor 232 is operative to assert the trigger pulse onto column driver 234 over terminal 233. The column driver is similar to those of FIG. 4A or FIG. 4C to that of FIG. 1D. The data configuration of column driver 234 can be set in a memory cell (not shown) forming a part of column driver 234 in response to a signal from the trigger signal control and generating circuit 231. In one embodiment, the data state of the memory cell of column driver 234 may be switched during operation to change the state of the voltage asserted on bitline 235p, thereby acting as a control over the timing of trigger signals on that bitline. Both bitlines 235p and 235n are driven with complementary data in order to match the capacitance of a regular bitline in the array of active pixels.

In instances where more than one word line and word line driver circuit is present on each row, a separate bit lines and column drive circuit similar to bitlines and column driver circuit 230 may be present for each word line driver circuit.

A voltage asserted onto bit column 235p is asserted onto sense circuit 237a over terminal 236a, onto sense circuit 237b over terminal 236b, onto sense circuit 237c over terminal 236c, onto sense circuit 237d over terminal 236d, onto sense circuit 237e over terminal 236e, onto sense circuit 237f over terminal 236f, and onto sense circuit 237g over terminal 236g. The outputs of sense circuits 237a through 237g are asserted in turn onto output terminals 238a through 238g respectively. A sense circuit may also be referred to as a sample circuit. Output terminals 238a, 238b, 238c, 238d, 238e, 238f, and 238g each are asserted onto a conductor similar to conductor 193 of FIG. 4B which in turns asserts the voltage onto a terminal of an AND gate of a plurality of row drivers (not shown) similar to row drivers comprising part of trigger circuit 140 of FIG. 1C. In one embodiment, a plurality of bitline pairs is implemented on a plurality of columns of an array of dummy pixels (not shown). Arrow 243 indicates the direction of propagation of the trigger signal on bitline 235p.

FIG. 4D depicts a detailed block diagram of a single tap circuit 280 after single tap circuit 190 of FIG. 4B. Tap circuit 280 comprises complementary bitlines 281p and 281n of an array of dummy pixels (not shown), tap 282, sense circuit 283, conductor 284, terminals 285a through 285g, column driver AND gates 286a through 286g and output terminals 287a through 287g. Complementary bitlines 281p and 281n are operative to deliver a release trigger signal from a control unit (not shown). All trigger signals are released on bitline 281p. In the initial state, bitline 281n is held high while bitline 281p is held low. When the trigger signal is released on bitline 281p, it is held high and bitline 281n switches to low. This insures that the RC characteristic of bitlines 281p and 281 match the RC characteristics of a pair of bitlines in the active array, therefore having substantially the same propagation delay. Tap 282 delivers a signal corresponding to the state of bitline 281p to sense circuit 283. Sense circuit 283 acts as previously described for FIG. 4A to drive conductor 284 with a conditioned signal to be delivered to a plurality of row drivers. Terminal 285a delivers the output of sense circuit 283 to one input port of two-port AND gate 286a wherein two-port AND gate 286a forms a part of a row driver circuit as shown in FIG. 1C. The second input to two-port AND gate 286a comes from the row decoder unit (not shown) as previously described for FIG. 1C. In like manner, terminals 285b, 285c, 285d, 285e, 285f and 285g deliver the output of sense circuit 283 to one port of two-port AND gates 286b, 286c, 286d, 286e, 286f, and 286g, the other port of those AND gates being connected to a row decoder unit (not shown). The outputs of AND gates 286a through 286g are asserted on output terminals 287a through 287g respectively. In one embodiment, terminals 287a through 287g assert the outputs of AND gates 286a through 286g on the input of voltage level shifters forming a part of a row driver circuit (not shown), In one embodiment, terminals 287a through 287g assert the outputs of AND gates 286a through 286g on the input of an inverter forming part of a row driver (not shown). Each row driver asserts its output onto a wordline (not shown). Only one row is selected by the row decoder circuit and therefore only one wordline is held high. Arrow 288 and arrow 289 indicate the direction of propagation of the signal on bitline 281p and on conductor 284 respectively. Because conductor 284 is parallel to bitline 281p with the same direction of propagation for a relatively small number of rows, the net propagation delay on bitline 281p is similar to the net propagation delay on conductor 284.

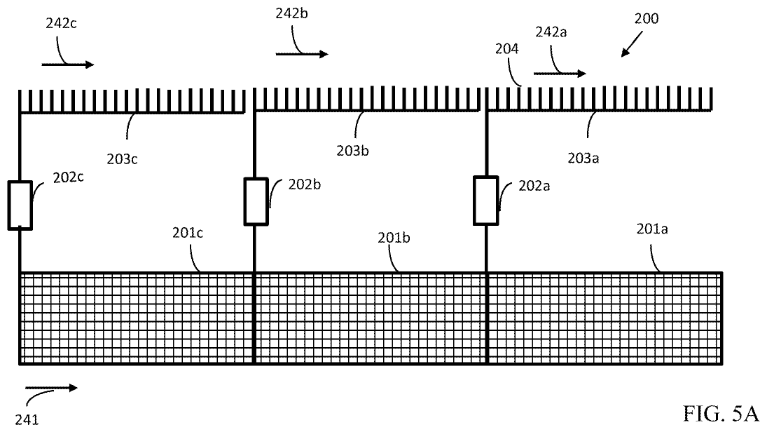

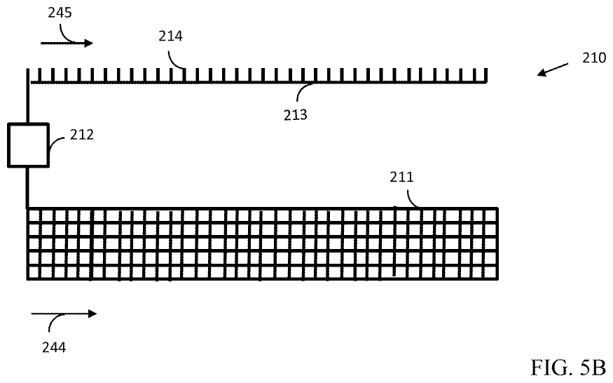

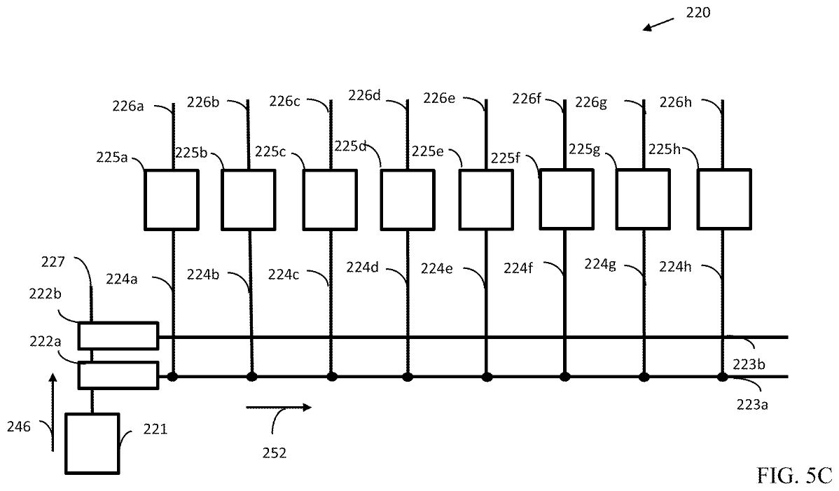

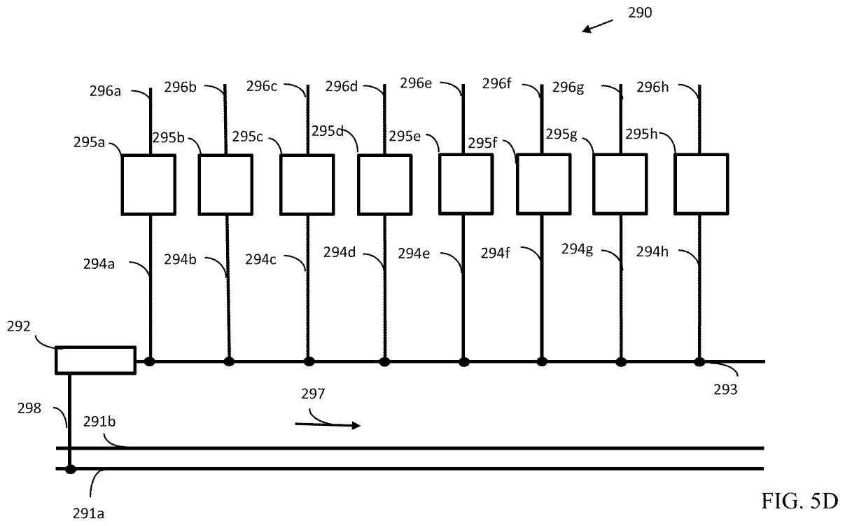

FIG. 5A depicts three segments 201a, 201b and 201c of an array of dummy pixels and associated circuitry 200 operative to provide an associated array of column drivers (not shown) with trigger signals to release data stored on a memory cell onto the bitlines of the associated array of column drivers (not shown) such as column driver 150 160 of FIG. 1D.and column driver 162 of FIG. 4C. The wordlines (not shown) of the array of dummy pixels are used as a means for delivering a signal to an associated set of column drivers initiating the release of complementary data onto the bitlines of an array of active pixels. The wordlines of segments 201a, 201b and 201c form a continuous wordline across all sections.

A tap on each of segments 201a, 201b and 201c of an array of dummy pixels is connected to circuit elements 202a, 202b and 202c respectively such that a signal present on the tapped wordline of segment.201a is asserted on circuit element 202a, a signal present on the tapped wordline of segment 201b is asserted on circuit element 202b and a signal present on the tapped wordline of segment 201c is asserted on circuit element 202c. In one embodiment, circuit elements 202a, 202b and 202c may be sense elements similar to sense elements 237a through 237g of FIG. 7C4C. The outputs of circuit elements 202a, 202b and 202c are asserted onto conductors 203a, 203b and 203c respectively. In one embodiment, the tapped wordlines of segments 201a, 201b and 201c are different wordlines of the array of dummy pixels.

Conductors 203a, 203b and 203c each assert the outputs received from circuit elements 202a, 202b and 202c respectively onto a series of column drivers (not shown) over a series of terminals 204 (one indicated). In one embodiment, each of terminal 204 is connected to CLK 166 of a corresponding column driver 162 of FIG. 4C. In one embodiment, each of terminal 204 is connected to a corresponding gate of load switch 152 of column driver circuit 150 160 of FIG. 1D.

The direction of propagation on segments 201a, 201b and 201c is indicated by arrow 241 adjacent to the array of dummy pixels. The direction of propagation of the tapped signal on conductors 203a, 203b and 203c are indicated by arrows 242a, 242b and 242c respectively. Conductor 203a is approximately half a pixel to a full pixel shorter than segment 201a, conductor 203b is approximately half a pixel to a full pixel shorter than segment 201b and conductor 203c is approximately half a pixel to a full pixel shorter than segment 201c. The difference in length serves to allow conductors 203a, 203b and 203c to be substantially colinear without being electrically connected. The signal asserted on conductor 203a by circuit element 202a lags the propagation of the trigger signal asserted on the wordline of segment 201a by a uniform factor determined by the propagation delay attributable to circuit element 202a. This same delay is induced by circuit elements 202b and 202c because the circuit elements are identical. Because all column drivers of the array of active pixels (not shown) are triggered by circuits identical to circuit 202a, the propagation delay across all conductors similar to conductor 203a includes a delay factor substantially equal to the propagation delay due to circuit element 202a.

FIG. 5B depicts a single segment 210 of array of dummy pixels 211 and associated circuitry after the three segments of FIG. 5A. Segment 210 comprises array of dummy pixels 211, a tap of a wordline operative to deliver a signal to the input of circuit element 212, conductor 213 operative to receive a signal from the output of circuit element 212, and a plurality of terminals 214 (one indicated). In one embodiment, circuit element 212 is a sense circuit. Each of terminals 214 is operative to assert the signal on conductor 213 on a column driver (not shown) such as those depicted in FIGS. 4A and 4C. In one embodiment, each of terminal 214 is connected to CLK 166 of a corresponding column driver 162 of FIG. 4C. In one embodiment, each of terminal 214 is connected to a corresponding gate or other release mechanism of a load switch (not shown) such as logic circuit 165 of column driver circuit 160 of FIG. 1D.

The structure of segment 210 is important. The direction of propagation of the release trigger signal with dummy pixel array segment 210 starts at the left size of array of dummy pixels 211 and moves to the right as indicated by the arrow. The trigger signal propagates through wordlines (not shown) of array of dummy pixels 211 at a velocity corresponding to the RC characteristic of the dummy wordline. A tap on wordlines (not shown) within array of dummy pixels asserts the trigger signal onto circuit element 212 which in turns asserts its output onto conductor 213. The tapped signal propagates on conductor 213 at a velocity corresponding to the RC characteristic of conductor 213 and the capacitance of the circuit elements in the column drivers to which it is attached over plurality of terminals 214 (one shown).

Because conductor 213 is parallel to the wordlines within array of dummy pixels and substantially coextensive, the discrepancy between conductor 213 and the wordlines is not extensive. The previous discussion from FIG. 4B above regarding physical line lengths applies to this case. It is important that the length is relatively short and that a series of taps at regular, although not necessarily equal intervals. Thus, the tapped signal propagates a relatively short distance on conductor 213 after which a new tap is made that propagates on a new conductor, as previously depicted for conductors 203c, 203b and 203a for FIG. 5A. This insures that any propagation differences are not cumulative across the entire wordline in array of dummy pixels 210 compared to the signal asserted on plurality of terminals 214 (one shown).

Arrow 244 indicates the direction of propagation along a wordline in the array of dummy pixels. Arrow 245 indicates the direction of propagation of the trigger signal from circuit element 212 on conductor 213. Circuit element 212 will have its own propagation delay that is a constant delay and the same for all circuits for delivering a trigger pulse to a column driver.

FIG. 5C presents a simplified drawing 220 of dummy wordlines 223a and 223b operative to deliver trigger signals to a set of column drivers (not shown) over a set of taps 224a-224h onto dummy wordline 223a. Dummy wordline 223b is always held low to provide a capacitive load comparable to the load on the wordline in the array of active pixels (not shown) wherein only one wordline is high and the surrounding wordlines are low.

In the embodiment wherein the array of pixel drive circuits is divided into vertical segments in which the rows of each section are serviced by separate row decoder circuits, the column drive circuits for the columns of each section are operated by a separate circuit similarly situated to that of the components of simplified drawing 220.

Row drivers 222a and 222b for an array of dummy pixels such as array of dummy pixels 211 of FIG. 5B.are configured to initiate at trigger pulse required to release data stored on a column driver such as the column drivers of FIG. 4A and FIG. 4C as previously described. Trigger timing control unit 221 delivers a signal to row drivers 222a and 222b over conductor 227 to deliver a signal to initiate a high trigger pulse on dummy wordlines 223a and 223b. In one embodiment, dummy wordline 223b is hard wired to a low state.

Taps 224a, 224b, 224c, 224d, 224e, 224f, 224g and 224h tap onto dummy wordline 223a in an array of dummy pixels such as array of dummy pixels 211 of FIG. 5B. Wordline 223b is held low. In one embodiment, wordlines 223b is hard wired to a low state.

Arrow 246 indicates the direction of propagation of a signal released by trigger control unit 221. Row drivers 222a and 222b assert values on dummy wordlines 223a and 223b of the array of dummy pixels responsive to the signal received from trigger control unit 221. Arrow 252 indicates the direction of propagation of the values asserted on dummy wordline 223a.

The logic behind holding an adjacent wordline in a low state is that in the array of active pixels, only one wordline is high and all other wordlines remain low. This creates a boundary condition that needs to be replicated in the array of dummy pixels in order for the capacitive load to match that of the array of active pixels in order to match the RC characteristic and therefore the propagation delay of the wordlines of the active array.

It is conceived within the present invention that more than two rows of dummy pixels may form a circuit to deliver signals to release data stored on a plurality of column drivers over more than one of the wordlines of the dummy pixels. In one embodiment, the taps may occur on a set of parallel wordlines with at least one intervening wordline that is held low. A wordline between the parallel tapped wordlines is held low. The choice for division into a first set and a second set of taps depends on the requirements of the particular display. If the display operates as a unitary system, then the division can be simple. If the division is into four major vertical stripes, wherein each strip is approximately a quarter of the columns, then a different design is needed. If the division is into four quadrants comprising upper left, upper right, lower left and lower right then yet another design is needed. All can be realized in one design at the price of significant complexity.

FIG. 5D depicts a detailed block diagram of a segment 290 of a column driver data release circuit after FIG. 5B. Segment 290 comprises dummy wordlines 291a and 291b, tap 298, sense circuit 292, conductor 293 and column drivers 295a-295h. Dummy wordlines 291a and 291b together act to form a circuit that substantially matches the RC characteristics of the wordlines of the array of active pixels (not shown), thereby matching the propagation delay between the dummy wordlines and the wordlines of the array of active pixels. Dummy word line 291a is pulled high by a signal from a trigger timing control unit such as unit 221 as described in FIG. 5C. Dummy wordline 291b is present to insure the capacitance loading on word line 291a is properly matched to a word line pulled high on the array of dummy pixels (not shown). The state of dummy wordline 291a at a given point is asserted over terminal 298 onto sense circuit 292. Sense circuit detects the state of dummy word line 291a and asserts a corresponding signal on conductor 293 with any needed signal conditioning. In one embodiment, sense circuit 292 detects the leading edge of the signal detected on dummy wordline 291a.

The signal asserted on conductor 293 is asserted onto each of column drivers 295a-295n over terminals 294a-294h. Column drivers 294a-294h, responsive to the state asserted onto its respective terminal 294a-294h, releases the data stored on its memory onto complementary bitlines 296a-296h respectively. Bitlines 296a-296h each represent a pair of complementary bitlines as described in FIG. 4.

Arrow 297 indicates the direction of propagation both on dummy wordline 291a and on conductor 293. The propagation delay on dummy wordline 291a is likely different to that on conductor 293 because the RC of the two lines are not identical. The propagation difference is not likely to be significantly different over a relatively short run. The use of multiple taps on a dummy bitline allows the line length to be equivalent to 32 or 64 pixel pitch lengths. For an 8.0 μm pixel pitch, this is 0.256 mm or 0.512 mm respectively. A serious propagation delay will not accumulate over such short distances even with a slight RC mismatch.

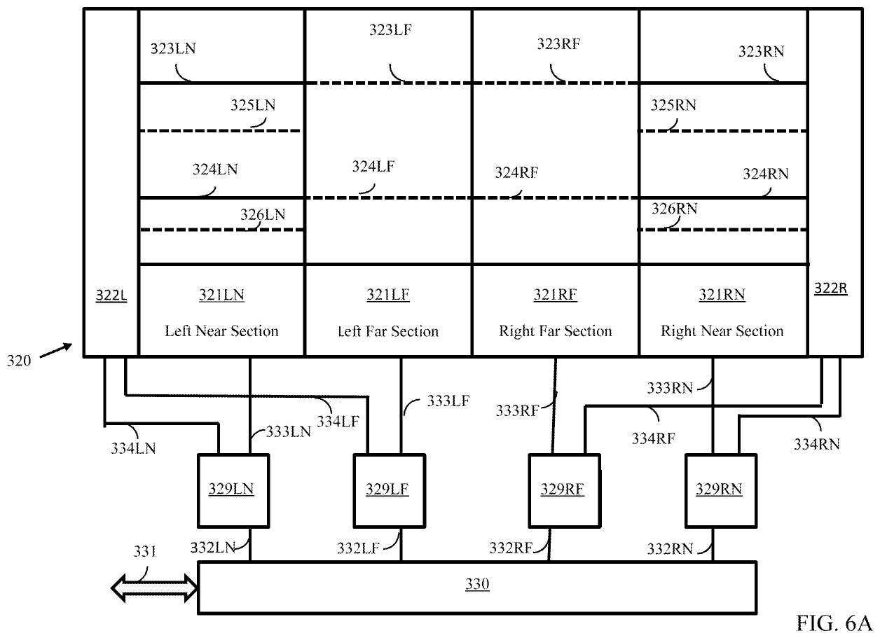

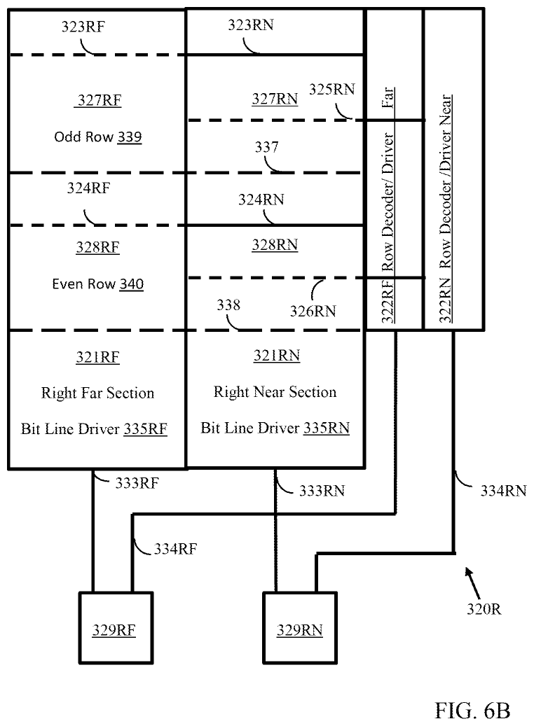

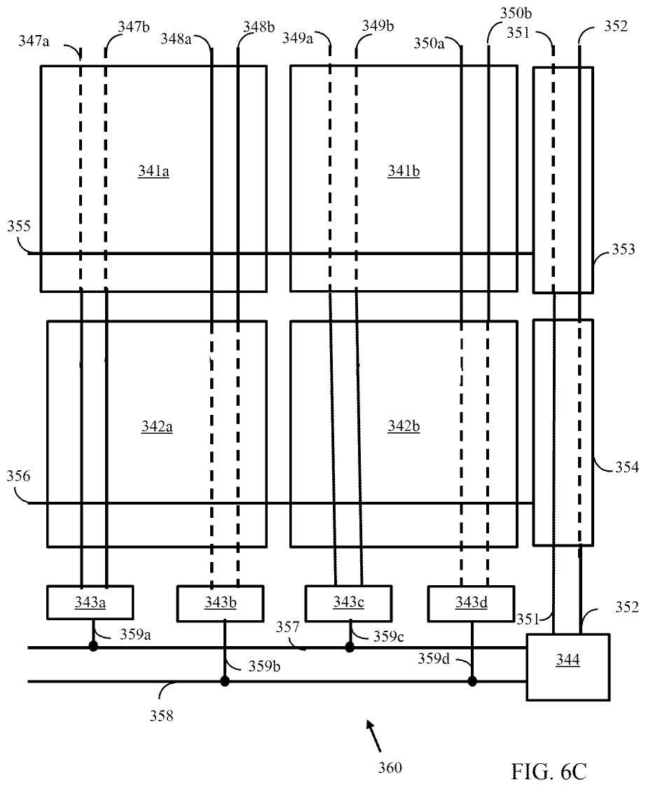

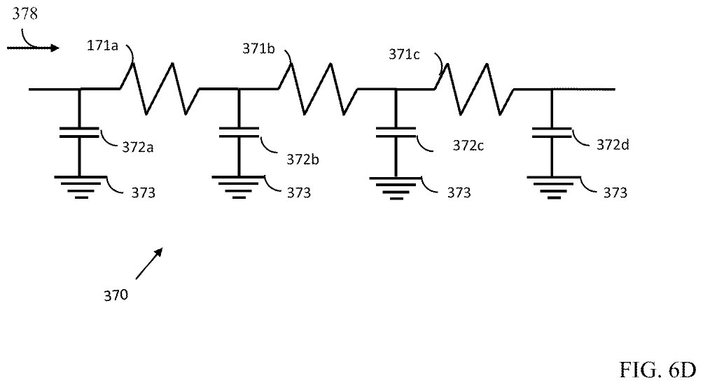

FIG. 6A depicts an arrangement whereby four controller devices 329LN, 329LF, 329RF and 329RN control a single backplane 320. The array of pixel drive circuits of backplane 320 is divided into four vertical sections, each of which has a controller associated with it. The descriptive convention for this application is that LN means left near, LF means left far, RF means right far, and RN means right near. The use of near and far means the relative distance to the row address circuitry found in left row decoder and word line driver 322L or the relative distance to the row address circuitry found in right row decoder and word line driver 322R.

The vertical sections comprise left near independent section of pixel drive circuits 321LN, left far independent section of pixel drive circuits 321LF, right far independent section of pixel drive circuits 321RF, and right near independent section of pixel drive circuits 321RN, hereafter referred to as sections. It is possible to make the width of the sections 321LN, 321LF, 321RF and 321RN substantially equal, but it is not strictly necessary that the vertical sections be substantially or exactly equal. Engineering considerations may dictate that they not all be equal. It is also possible to make the width of the left side sections combining 321LN and 321LF not equal to the width of the right side sections combining 321RN and 321RF for engineering reasons. Note that none of the independent sections of pixel drive circuits 321LN, 321LF, 321RF and 321RN overlap with any of the other independent sections of pixel drive circuits 321LN, 321LF, 321RF or 321RN.

Complete image data for the array of pixel drive circuits is received by image data preprocessor 330 over bus 331. Image data preprocessor 330 processes the incoming image data to separate it into data for left near section 321LN, left far section 321LF, right far section 321RF and right near section 321RN and delivers that data to display controller 329LN, display controller 329LF, display controller 329RF and display controller 329RN over terminals 332LN, 332LF, 332RF, and 332RN respectively. Display controller 329LN, display controller 329LF, display controller 329RF, and display controller 329RN process the data and schedules it to be written to the required row. All display controllers 329LN, 329F, 329RF, and 329RN and preprocessor 330 operate on the same master clock set by a crystal controlled circuit (not shown) or similar devices. This does not keep them precisely synchronized because each display controller synchronizes to the master clock signal with its individual digital phase lock loop which will run slightly asynchronous to the other digital phase lock loops. Each display controller also receives a Vsync (vertical synchronization) signal from circuitry associated with image data preprocessor 330. Vsync will keep the frame rate of each image section in sync with the frame rates of all other image sections. They will normally be within a clock cycle or two, which has negligible effect on image quality between vertical sections.

In one embodiment, the data transferred to the column data registers by each display controller is not limited to the boundaries of each independent segment of pixel drive circuits with which is associated through the row select assembly.

There are other methods of developing and implementing a display controller assembly. In one approach, all required display controllers are designed and implemented in a single semiconductor device. This may make some aspects easier to implement, but the federated approach presented herein offers some advantage with respect to yield due to the smaller silicon size for the individual display controllers. Also, the striped display approach to the backplane is compatible with either approach to the display controller.

A device termed as a single display controller or display controller assembly wherein each display controller controls a section of a display may be comprised of a number of separate elements, such as multiple semiconductor devices, within the spirit of this invention.

Row decoder and word line driver 322L comprises a pair of row decoders and word line drivers; one for display controller 329LM and one for display controller 329LF. Display controller 329LN delivers word line address and a row trigger control signal over line 334LN to row decoder and word line driver 322L. At the same time display controller 329LN delivers image data for the addressed row onto a set of bit line drivers over conductor 333LN for left near section 321LN (not shown.) The relative timing requires that data for all pixel drive circuits of the addressed row be in place before the word line driver pulls the word line for that segment of the row high. Propagation delay can be taken into account as long as the propagation rates across the display and up the display to insure that the complementary bit lines for that column are in their data state at that row before the word line pulls high at that point on the row.

Display controller 329LF delivers word line address and a row trigger signal over line 334LF to the second of two row decoder and word line driver circuits in row decoder and word line drive 322L. At the same time display controller 329LF delivers image data for the addressed row onto a set of bit line drivers over conductor 333LF. The same considerations for propagation delay addressed for display controller 329LN apply to display controller 329LF.

Row decoder and word line driver 322R comprises a pair of row decoder and word line driver circuits after the circuits of row decoder and word line driver 322L. Display controller 329RF delivers word line address and a row trigger signal over line 334RF to one of a pair of row decoder and word line driver circuits in row decoder and word line driver 322R. Display controller 329RF delivers image data for right far section 321RF to the bit line drivers over conductor 333RF with the previously noted timing conditions.

Display controller 329RN delivers a word line address and a row trigger signal over line 334RN to the second of two row decoder and word line driver circuits in row decoder and word line drive 322R. Display controller 329RN delivers image data for right near section 321RN over conductor 333RN with the previously noted timing conditions.

In one embodiment, display controllers 329LN, 329LF, 329RF and 329RN operate physically separated trigger circuits similar in function and location to

When row decoder and word line driver 322L receives a row address from display controller 329LN on a first row decoder and word line driver circuit, the word line of the row corresponding to the address is held to a state that enables the memory circuits operated by that word line to receive data over the bit lines when a trigger signal is received over the same connection. Dashed line 325LN represents a word line for a first row of near left section 321LN and dashed line 326LN represents a word line for a second row of near left section 321LN. Because section 321LN is near to row decoder and word line driver, word line 325LN and word line 326LN do not extend into left far section 321LF. For reasons of constant metal density, a dummy metal structure may be positioned in left far section 321LF to improve the planarity of the die forming the backplane, a consideration of importance for liquid crystal and other devices.

When row decoder and word line driver 322L receives a row address from display controller 329LF on a second row decoder and word line driver circuit, the row corresponding to the address is held high when a trigger signal is received over the same connection. Word line 323LN passes under left near section 321LN without making electrical connection and reaches word line 323LF, which is connected to the SRAM memory cells of each pixel drive circuit in left far section 321LF. Identical considerations hold true for word line segments 324LN and 324LF.

The RC value of word line 323LN combined with word line 323LF will be greater than the RC value of 326LN because of the resistance associated with the length of 324LN that passes under left near section 321LN, although, if the sections are not of equal width, that must also be taken into account. The RC characteristic is part of the definition of transport delay in propagating the change in the word line from low to high and back to low.

Similar considerations apply in the case of word line 325RN and 326RN, which both connect to a row of pixel drive circuits in right near section 321RN. Likewise, word line 323RN passes under right near section 321RN in order to connect to word line segment 323RG, which connects to SRAM memory cells in pixel drive circuits forming a row of right far section 321RF. The same consideration applies to word line segment 324RN which connects to word line segment 324RF.

FIG. 6B presents a more detailed block diagram view of parts of the right half of the system of FIG. 2A. The expanded view comprises display controller 329RF, display controller 329RN, and partial backplane 320R. Partial backplane 320R comprises right far section 321RF, right near section 321RN, row decoder and word line driver (right far section 322RF), and row decoder and word line driver (right near section) 322RN. The relative positions of row decoder and word line driver 322RF and of row decoder and word line driver 322RN is selected for ease of explanation. They may in fact be developed in different layers and stacked vertically, depending on the number of metal layers of the backplane semiconductor. Other arrangements are possible.

Right far section 321RF comprises bit line driver 335RF, even row pixel drive circuit 328RF and odd row pixel drive circuit 327RF. Right near section 321RN comprises bit line drive circuit 335RN, even row pixel drive circuit 328RN and odd row pixel drive circuit 327RN. Odd row 339 comprises pixel drive circuit 327RF and pixel drive circuit 327RN, and even row 340 comprises pixel drive circuit 328RF and pixel drive circuit 328RN. For clarity, dashed line 337 represents the boundary between the pixel driver circuits of odd row 339 and the pixel driver circuits of even row 340. Dashed line 338 represents the boundary between the pixel driver circuits of even row 340 and bit line driver 335RF and bit line driver 335RN.

Display controller 329RF delivers image data to bit line driver 335RF over conductor 333RF. Conductor 333RF comprises a substantial plurality of parallel data paths. Display controller 329RF sends row address information to row decoder and word line driver 322RF over conductor 334RF. In one embodiment, a separate trigger signal is sent over conductor 334RF to pull the word line high when timing is important. This can be implemented using an AND gate (not shown) with two input ports and one output. The selected row receives one input from the row decoder and the second from the trigger signal and the output is connected to the word line. Only one AND gate will have a high input on both input ports, which will result in the output of the AND gate pulling the word line high.

Digital controller 329RN delivers image data to bit line driver 335RN over conductor 333RN. Conductor 333RN comprises a substantial plurality of parallel data paths. Display controller 329RN sends row address information to row decoder and word line driver 322RN over conductor 334RN. In one embodiment, a separate trigger signal is sent over conductor 334RN to pull the word line high when timing is important. This can be implemented using an AND gate with two input ports and one output. The selected row receives one input from the row decoder and the second from the trigger signal and the output on the word line. Only one AND gate will have a high input on both input ports, which will result in the output of the AND gate pulling the word line high.

Pixel drive circuit 327RF is the portion of odd row 339 that lies in right far section 321RF. In practical embodiments, right far section 321RF may comprise 500 to 1000 pixel drive circuits or more, although other number of pixel driver circuits are not excluded. Similar considerations may be applied to pixel drive circuit 327RN, pixel drive circuit 328RF and pixel drive circuit 328RN.

Row decoder and word line driver far 322RF is operative to drive two word lines sets in each row. Word line segment 323RN passes under pixel drive circuit 327RN of odd row 339 to connect to word line segment 327RF where it makes contact with the SRAM memory cell of pixel drive circuit 327RF. Row decoder and word line driver near 322RN drives word line segment 325RN which makes contact with the SRAM memory cell of pixel drive circuit 327RN.

Row decoder and word line driver 322RF is operative to drive word line segment 324RN that passes under pixel drive circuit 328RN of even row 340 to connect to word line segment 324RF where it makes contact with the SRAM memory cell of pixel drive circuit 328RF.

In one embodiment, word line segments 223RN and 223RF and word line segment 225RN of odd row 239 are pulled high at substantially the same time with some allowance for differing propagation delays. Alternatively word line segments 224RN and 224RF and word line segment 226RN of even row 240 are pulled high at substantially the same time with some allowance for differing propagation delays. The choice of row on which the word lines are pulled high depends on the address data sent to row decoder and word line drivers 222RF and 222RN.

For display applications generating images for viewing by humans, it is best to keep the near and far sections on the same schedule. This will help control the generation of visual artifacts from such causes as lateral field effects. For other applications there may be advantages to placing the near and far sections on differing schedules.

FIG. 6C depicts an additional way in which the time required to write an array can be reduced. Display system 360 comprises four pixel drive circuits 341a, 341b, 342a, and 342b arranged in a 2×2 matrix format. Display system 360 further comprises row decoder and word line drivers 353 and 354, and bit line drivers 343a, 343b, 343c and 343d, and display controller 344. It is to be understood that a practical arrangement will have many more rows and columns than are depicted here.

Pixel drive circuits 341a and 341b form an odd numbered row of pixel drive circuits and pixel drive circuits 342a and 342b form an even number row of pixel drive circuits. Row decoder and word line driver 353 drives word line 355 associated with odd row pixel driver circuits 341a and 341b. Row decoder and word line drive 354 drives word line 356 associated with even row pixel driver circuits 342a and 342b.

Bit line driver 343a supplies complementary binary image data to the SRAM memory cell of pixel driver circuit 341a on an odd numbered row over complementary bit lines 347a and 347b. Bit line driver 343c supplies complementary binary image data to the SRAM memory cell of pixel driver circuit 341b on an odd numbered row over complementary bit lines 349a and 349b. Complementary bit lines 347a and 347b and complementary bit lines 349a and 349b pass underneath pixel drive circuits 342a and 342b located on an even numbered row.

Bit line driver 343b supplies complementary binary image data to the SRAM cell of pixel drive circuit 342a on an even numbered row over complementary bit lines 348a and 348b. Bit line driver 343d supplies complementary binary image data to the SRAM memory cell of pixel drive circuit 342b over complementary bit lines 350a and 350b. Complementary bit lines 348a and 348b and complementary bit lines 350a and 350b pass under pixel drive circuits 341a and 341b in an odd numbered row. It is understood that further even numbered rows may be positioned above the odd numbered row of pixel drive circuits 341a and 341b.

Data for odd numbered rows is supplied to bit lines drivers 334a and 343c over bus line 357 by terminals 359a and 359c. Data for even numbered rows is supplied to bit line drivers 334b and 334d over bus line 358 by terminals 359b and 359d. Bus lines 351 and 352 comprise a plurality of parallel lines used to transmit address data for the selected row to row decoder and word line drivers 353 and 354 respectively. In one embodiment, bus lines 351 and 352 comprise a word line trigger signal conductor that controls the timing of the action to pull the word line high.

FIG. 6D presents a depiction of the RC characteristics 370 of a word line after word line segment 323RN combined with word line segment 323RF of detailed block diagram 320R of FIG. 6B. Vector 378 represents the direction of propagation of the row select signal on the word line. Resister 371a represents the resistance and capacitor 372a represents the parasitic capacitance of word line segment 323RN which passes under right near section 321RN of detailed block diagram 320R. Note that all depicted capacitances are connected to ground 373. Other grounding configurations may be possible as the parasitic capacitance for word line segment 323RN may be influenced by another nearby conductor at a different potential rather than by a ground plane.

Capacitors 372b, 372c and 372d represent the capacitance at nodes where word line segment 323RF intersects with circuit elements, such as pass transistors 128 and 129 of 6-transistor SRAM memory 120 of FIG. 1B. A general expectation is that the capacitance due to interaction at the nodes would be significantly greater than the parasitic capacitance due to the presence of other circuit elements nearby, although there are exceptions to this that depend on the specifics of the semiconductor manufacturing process and the design rules associated with the chosen process. Modern semiconductor computer aided design (CAD) software tools allow detailed evaluations to be conducted prior to manufacturing and testing the silicon design.

The value of resistance R for a segment of a conductor can be calculated is presented in the discussion of FIG. 3 and is repeated here in simplified form. Applicant refers the reader to that text. As previously noted, all conductors in the same layer of a semiconductor process are typically made of the same material, such as aluminum or copper, and will therefore have a similar resistivity σ and height H. The length L and width W can be varied but the resistance per unit length will be the same if the resistivity σ and width W are the same. One manner in which the resistance of a wire of a given unit length can be reduced is by increasing the width W. Care must be taken when doing this because the reduction in resistance R may be accompanied with an increase in stray capacitance C, which may result in a less than desired reduction in the RC characteristic of the conductor. This in turn would limit or eliminate any increase in signal propagation speed on such a line.

A useful goal is a reduction in the time required for a word line select signal to propagate along a word line after the word line described above comprising word line segment 323RN combined with word line segment 323RF. Word line segment 323RN does not interact with the memory circuits of right near section 321RN of pixel drive circuits whereas word line segment 323RF interacts with the memory circuits of right far section 321RF of pixel drive circuits. Word line segment 325RN interacts with the memory circuits of right near section 321RN. The word lines selected for this example address one row of many rows, all of which may be addressed in a similar manner.

The time required to propagate across right near section 327RN on word line segment 325RN is determined by the RC characteristic of the line. The signal from word line segment 325RN is not propagated into right far section 321RF because the memory circuits on the same row of right far section 321RF are controlled by a signal on word line segment 323RF received through word line segment 323RN, as previously noted.

In one embodiment, word line segment 323RN that does not interact with the memory circuits on its row of right near section 321RN is routed near to word line segment 325RN. This may be a desirable design choice for a number of reasons unrelated to capacitance, such as a desire to maintain a constant metal density on individual layers of the semiconductor to preserve its planarity, an important consideration for liquid crystal devices such as liquid crystal on silicon light modulators.

Applicant has developed several backplanes of different sizes in different processes with an active resolution of 4096 columns by 2400 rows. By applying the four display controller approach as disclosed herein and also using the even row-odd row approach, the nominal size of display that each display controller subchannel must handle becomes 1024 wide by 1200 tall, which is substantially manageable. The ultimate requirement, then is for four pairs of display controller subchannels, which is effectively eight subchannels.

Delay in the propagation of data and signals in a backplane is of the utmost importance when using an older process with aluminum wiring, especially if the part is large in integrated circuit terms. Applicant is separately filing a separate patent application describing means for minimizing the delays within a backplane by speed matching the bit lines to the word line control and by speed matching the word line propagation to the bit line trigger signal.

FIG. 7A presents a depiction of the left side of a display 400 with 4 vertical sections of pixel drive circuits. Left display side 400 comprises leftmost vertical section of pixel drive circuits 401LN and left of center vertical section of pixel drive circuits 401LF. Left display side 400 further comprises display controller 402LN operative to control vertical section of pixel drive circuits 401LN, display control 402LF operative to control vertical section of pixel drive circuits 401LF, row of bit line drivers 412LN operative to deliver complementary bit line data to the pixels of vertical section of pixel drive circuits 401LN, and row of bit line drivers 412LF operative to deliver bit line data to the pixels of vertical section of pixel drive circuits 301LF. All segments may be resident in a same physical semiconductor assembly. Left display side 400 comprises row decoder and word line driver assembly 404LN operative to drive the word line of the selected row in vertical section of pixel drive circuits 401LN and row decoder and word line drive assembly 404LF operative to drive the word line of the selected row in vertical section of pixel drive circuits 401LF.

Display controller 402LN and display controller 402LF receive row address and row data information for their respective vertical sections from an image data preprocessor such as image data preprocessor 330 of FIG. 6A. Each display controller controls its vertical section of pixel drive circuits without regard to adjacent display controllers. The display controllers are programmed to operate in a similar manner with respect to rows to be written and are synced to the same clock. As a result, the adjacent vertical sections normally operated within a few clock cycles of each other.

The image data for a given row within vertical section of pixel drive circuits 301LN is loaded by display controller 402LN onto bit line drivers 406LN1 and 406LN2 of row of bit line drivers 412LN for the pixel drive circuits of vertical section of pixel drive circuits 401LN over terminal 410LN. The pixel drive circuits associated with bit line driver 406LN1 comprise pixel drive circuits 1Na, 1Nb, 1Nc, 1Nd and 1Ne, and the pixel drive circuits associated with bit line driver 306LN2 comprise pixels drive circuits 2Na, 2Nb, 2Nc, 2Nd and 2Ne. Bit line drive 406LN1 loads the bit line data for the selected pixel onto complementary bit lines 413LN1, which are marked with a + (plus) sign or a − (minus) sign for B_{POS} or B_{NEG} respectively. Bit line drive 406LN2 loads the bit line data for the selected pixel onto complementary bit lines 413LN2. As before, the complementary bit lines are marked with a + sign or a − sign.

The image data for a given row with vertical section of pixel drive circuits 401LF is loaded by display controller 402LF onto bit line driver 406LF1 and 406LF2 of row of bit line drivers 412LF for the pixel drive circuits of vertical section of pixel drive circuits 401LF over terminal 410LF. The pixel drive circuits associated with bit line driver 406LF1 comprise pixel drive circuits 1Fa, 1Fb, 1Fc, 1Fd and 1Fe, and the pixel drive circuits associated with bit line drive 306LF2 comprise 2Fa, 2Fb, 2Fc, 2Fd and 2Fe. Bit line driver 406LF1 loads the bit line data for the selected pixel onto complementary bit lines 413LF1, which are marked with a + (plus) sign or a − (minus) sign for B_{POS} or B_{NEG} respectively. B bit line driver 306LF2 loads the bit line data for the selected pixel onto complementary bit lines 313LF2. As before, the complementary bit lines are marked with a + (plus) sign or a − (minus) sign.

Left display side 400 comprises rows 405a, 405b, 405c, 405d and 405e, each of which comprises a left near row decoder and wordline driver in row decoder and word line driver assembly 404LN, a left far row decoder and word line drive in wordline driver assembly 4004LF, two pixels in a left near vertical section and two pixels in a left far vertical section. For example, row 405a comprises left near row decoder and word line driver LNa, left far row decoder and word line drive driver LFa, pixel drive circuits 1Na and 2Na of left near section 401LN and pixel driver circuits 1Fa and 2Fa of left far section 401LF. Rows 405b, 405c, 405d and 405e are organized identically with their constituents.

Left display side further comprises trigger signal circuit 403LN and trigger signal circuit 403LF. Trigger signal circuit 403LN receives a signal or set of signals over bus 409LN from display controller 402LN. Trigger signal circuit 403LN releases a bit line trigger signal over bus line 408LN and row select and word line high signals over bus line 407LN. In one embodiment, trigger signal circuit 403LN forms a part of display controller 402LN. Trigger signal circuit 403LF receives a signal or set of signals from display controller 302LF over bus 409LF. Trigger signal circuit 403LF releases a bit line trigger signal over bus line 408LF and row select and word line high signals over bus line 407LF. In one embodiment, trigger signal circuit 403LF forms a part of display controller 402LF.

Row select and word line high trigger signals delivered over bus 307LN to row decoder and word line driver assembly 304LN cause the following actions to take place. The row decoder logic in one of row decoder and word line driver LNa, LNb, LNc, LNd and LNe will go high in response to the row select signals delivered to row decoder and word line driver assembly 304LN. In a first embodiment, the output of the word line driver of each row is applied to the input of a two input AND gate (not shown). The word line trigger signal is applied to the other input of each of the AND gates. Only the selected row receives an input from both the row select decoder logic and the word line trigger signal, allowing that word line to be held high by the output of the AND gate. In one embodiment, the row decoder logic pulls the word line high without the word line trigger signal.

Word line driver LNa drives word line 411a, which provides the word line signal to the memory circuits of pixel drive circuits 1Na and 2Na of vertical section of pixel drive circuits 401LN. Word line 411a does not extend into vertical section of pixel drive circuits 401LF. In like manner word line drive LNb drives word line 411b, which provides the word line signal to the memory circuits of pixel drive circuits 1Nb and 2Nb of vertical section of pixel drive circuits 401LN. Word line drivers LNc, LNd, and LN3 drive word lines 411c, 411d and 411e respectively, which provide word line signal to the memory circuits of the pixel drive circuits of their respective rows.

Row select and word line high signals delivered over bus 407LF to row decoder and word line driver assembly 404LF cause the following actions to take place. The row decoder logic in one of row decoder and word line driver LFa, LFb, LFc, LFd and LFe will go high in response to the row select signals delivered to row decoder and word line driver assembly 404LF. In a first embodiment, the output of the word line driver of each row is applied to the input of a two input AND gate (not shown). The word line trigger signal is applied to the other input of each of the AND gates. Only the selected row receives an input from both the row select decoder logic and the word line trigger signal, allowing that word line to be held high. In one embodiment, the row decoder logic pulls the word line high without the trigger signal or the presence of the AND gate.

Word line driver LFa drives word line 441a, which provides the word line signal to the memory circuits of pixel drive circuits 1Fa and 2Fa of vertical section of pixel drive circuits 401LF. Word line 414a passes under the pixel circuits of vertical section of pixel drive circuits 401LN without making electrical connection. In like manner word line drive LFb drives word line 414b, which provides the word line signal to the memory circuits of pixel drive circuits 1Fb and 2Fb of vertical section of pixel drive circuits 401LF. Word line drivers LFc, LFd, and LFe drive word lines 414c, 414d and 414e respectively, which provide word line signal to the memory circuits of the pixel drive circuits of their respective rows.

Trigger circuit 403LN delivers a bit line driver trigger signal to bit line drivers 406LN1 and 406LN2 of row of bit line driver circuits 412LN. This releases the data previously loaded onto bit line drivers 406LN1 and 406LN2 by display controller 402LN. The data and its complement are loaded onto complementary bit lines 413LN1 by bit line driver 406LN1 and onto complementary bit lines 413LN2 by bit line driver 406LN2.

Trigger circuit 403LF delivers a bit line driver trigger signal to bit line drivers 406LF1 and 406LF2 of row of bit line driver circuits 412LF. This releases the data previously loaded onto bit drivers 406LF1 and 406LF2 by display controller 402LF. The data and its complement are loaded onto complementary bit lines 413LF1 by bit line driver 306LF1 and onto complementary bit lines 413LF2 by bit line driver 406LF2.

Control over timing of the word line and the bit line is essential to the efficient operation of a backplane. In general, the bit line at a particular pixel of a selected row has to be loaded with the complementary data for that pixel before its word line is pulled high. It is also important that the previous word line held high should be turned off before the data for the new pixel of the next selected row reaches the pixel of the old row. Turning off the word line for the old row can be accomplished by either removing the word line trigger signal for cases where the word line trigger signal is required or by selecting the new row in the case where there is no word line release signal.

In FIG. 7B, an SRAM array 420 that is m columns wide by n rows high is presented for discussion of propagation delay. For this example, a bit line trigger signal for the release of image data onto the bitlines and a word line trigger signal to activate circuitry associated with the row drivers to pull the wordline high are presumed to originate in circuitry proximate to coordinates (0,0) in the lower left-hand corner of the array. It is understood that trigger signals may originate in more than one location. For example, one location may be proximate to the lower left corner of the pixel array and a second location may be proximate to the lower right corner of the pixel array, and wherein the lower left trigger circuit location may handle the left half of the array and the lower right trigger circuit location may handle the right half of the array.

In an embodiment after the system of FIG. 6A, a display controller may be located at a position away from the corner of the array. In addition, word lines associated with that display controller may also pass under a section of pixel drive circuits to reach a portion of an array where the word lines do connect to the memory circuits of pixel drive circuits. These positions do add to the time required for the word line to pull high at a particular point on the array, but the added time can be taken into account and the added time due to the requirement to pass under another section of pixel drive circuits is invariant for pixels within that portion of the array. The difference in time to propagate across the pixels of that portion of the display once the signal reaches the closest pixel circuit is determined by the RC characteristic of the word line in that section.

Considering the wordline path above, the time from when the word line trigger signal is sent from coordinates adjacent to coordinate (0, 0) to the AND gate until the word line trigger signal arrives at the AND gate adjacent to coordinate (0, y) is depicted as TR₁. TR₁ represents the time required for the bit line trigger signal to propagate from the point adjacent to coordinate (0, 0) to coordinate (0, y). The use of distance to represent time is appropriate because the propagation delay along that path has a uniform characteristic when the circuits carrying a signal on that part of the path are uniform and repetitive. The second part of the path is wordline 422. The wordline for an array of SRAM type memory cells is connected to the gates of pass transistors such as transistors 128 and 129 of SRAM circuit 120 of FIG. 1B. The resistance of the wordline conductor and the capacitance of the wordline and of the connections to the pass transistors define the RC characteristic of the wordline and therefore the propagation delay of the wordline. The RC characteristic of the wordline may differ from the RC characteristic of the line on which the word line trigger signal used as an input to the AND gate at each row driver propagates.

In the case wherein the pixel pitch in the x direction is a uniform X distance units laterally across the display and the pixel pitch in the y direction is a uniform Y distance units vertically on the display, pixel location (x, y) is at a physical position relative to the origin at (0, 0) of X distance units times x laterally and Y distance units times y vertically. The choice of distance unit is arbitrary, although most modern pixels are specified in microns, or millionths of a meter from center to center.

The same considerations can be applied to other display geometries such as a parallelogram provide the opposite sides are of equal length and parallel, such as a rhomboid. It can also be applied in modified form to a display with a pixel format that is anamorphic on one of its principal axes. The principle difference is that the pixel pitch on that axis is not uniform, requiring use of other types of calculations for distance, such as a lookup table.

There are other delays inherent in logic components such as AND gates. These delays are of uniform character for each row and do not vary from row to row, making them predictable in that all pixels of all rows have the same delay from that source inherent upon them.

As an example, consider the pixel circuit at coordinates (x, y) of FIG. 7B. The pixel drive circuit on the row immediately below it will be located at coordinates (x, y−1) and the pixel drive circuit on the row immediately above it will be located at coordinates (x, y+1.) The time for a signal to propagate from coordinate (0,y) at the left edge of the array to coordinate (x, y) is identical to the time required for a signal to propagate from coordinate (0, y−1) to coordinate (x, y−1) and to the time required for a signal to propagate from coordinate (0, y+1) to coordinate (x, y+1). The time required for a signal to propagate from coordinate (0, 0) to coordinate (0, y) is greater than the time required for a signal to propagate from coordinate (0, 0) to coordinate (0, y−1) and less than the time required for a signal to propagate from coordinate (0, 0) to coordinate (0, y+1). This results from the difference in path length along the Y-axis.

The time from when the bit line trigger signal to the bit line driver to release complementary data onto the bitlines is initiated and its arrival at the bit line driver and the time from the release of data from the bit line drivers until the data arrives at the pixel of interest (x, y) in the array together require a variable amount of time, wherein that variation depends mainly on the path lengths of the two segments and the individual RC (resistance times capacitance) characteristics of the circuits forming the two segments along which this propagates.

The path that brings the bit line trigger signal from the bit line trigger initiating circuit to the bit line driver extends from coordinates (0, 0) to (x, 0) along the X-axis of array 420. The time required for the signal to propagate that distance is designated as TB₁. The duration of TB₁ is determined by the RC characteristic of the conductor over which the bit line trigger signal propagates. The RC characteristic is in turn determined by the physical characteristics of the conductor, which comprise resistive and capacitive coupling components and the physical characteristics of any transistor nodes along the path, which primarily comprise capacitive coupling components. This may be thought of as a network. The actual voltage of the bit line trigger signal does not affect the RC characteristic of a network.

The second part of the path that delivers image data over the complementary bitlines to the pixel of interest is initiated when the image data is released from the bit line driver circuit. There are inherent delays within the bit line driver circuits that are substantially identical for all columns. The propagation delay from the time the image data is released onto the bitlines for the pixel of interest until the image data arrives at the pixel of interest on the selected row depends on the distance from the bit line driver to the pixel of interest in addition to the bitline characteristics, especially the RC delay. For analysis, the time delay is noted as TB₂. TB₂ is the time required for the image data to propagate from coordinate (x, 0) to coordinate (x, y) of the pixel of interest over bit lines 423. The additional delay due to various logic circuits can be lumped together as TB₃ (not shown) and treated as a constant value not dependent on the pixel position. The total delay TB_{TOT} (not shown) due to propagation delay from the bit line trigger source to the pixel of interest is TB_{TOT}=TB₁+TB₂+TB₃.

The wordline path begins with the path from a word line trigger initiation that delivers the word line trigger signal up the side of the display from coordinate (0, 0) to coordinate (0, y). The actual path is slightly outside the array but is parallel to the Y-axis as depicted. The time required for the word line trigger signal to propagate along this first path is TR1. The duration of TR1 is, as before, determined by the RC characteristic of the line over which the word line trigger signal propagates to reach the row driver at coordinate (0, y). The second part of the wordline path is the wordline itself. The wordline on the selected row is pulled high when the word line trigger signal reaches the AND gate which forms part of the row driver circuit. The propagation time, TR₂, is determined by the RC characteristics of the wordline. The additional delay due to various logic circuits can be lumped together as TR₃ (not shown) and treated as a constant value not dependent on the pixel position. The total delay TR_{TOT} (not shown) due to propagation delay from the word line trigger source to the pixel of interest is defined as TR_{TOT}=TR₁+TR₂+TR₃.

An observation based on the calculations for FIG. 7B is that the physical length associated with the path for TB₁ added to the length of the path TB₂ is substantially equal to the physical length associated with the path for TR₁ added to the length of the path for TR₂. Another evident characteristic is that the physical length associated with TR₁ is substantially equal to the physical length associated with TB₂ and the physical length associated with TR2 is substantially equal to the physical length associated with TB₁.

Note that the RC characteristic associated with the path for TR₁ is not likely to match the RC characteristic associated with the path for TR₂ absent a serious design requirement to make those RC characteristics match, and that the RC characteristic associated with the path for TB₁ does not need to match the RC characteristic associated with the path for TB₂. If both the RC characteristic and the physical length associated with a first circuit are substantially equal to the RC characteristic and physical length associated with a second circuit, then the propagation delay along the two circuits will be substantially equal.

Based on the observation above that the physical path length associated with TR₁ is substantially equal to the physical path length associated with TB₂, it follows that the propagation delays associated with the two physical paths can yield similar propagation delays if the RC characteristics of the two physical paths are substantially the same. The same consideration regarding RC characteristics applies to the case of the path length associated with TR₂ and the path length associated with TB₁. The difficulty lies in identifying means by which the entire length of the circuit carrying the word line trigger signal to the row decoder can be RC matched to the bitlines acting as circuits to carry data to the pixels of the selected row.

This and a similar consideration for RC matching between the path length associated with the bit line trigger signal to the bit line driver and the wordline from the row decoder to the pixel of interest (x, y) is addressed in the present application. Stated in other terms, it is important that the equation TR₁+TR₂=TB₁+TB₂ is substantially satisfied. The design procedures disclosed in the present application support achieving that result.

RC matching is the subject of significant development effort in the design of semiconductor devices. Much of the work is devoted to design techniques and practices that reduce the effects of any mismatches in RC matching. While useful for many pure memory designs, techniques such as dividing the wordline into many sub wordlines are less useful in the field of displays based on memory devices at each pixel when the goal is to write an entire line of data to the display as rapidly as possible rather than to write a single word to a portion of a row.

FIG. 7C depicts a case wherein the display is divided into vertical sections 441 and 442. Again SRAM array 440 comprises an array of pixel drive circuits, each comprising a memory cell, of m columns by n rows. The dividing line for vertical sections 441 and 442 is vertical dashed line 445 between coordinates (m′, 0) and (m′, n) M′ is m prime. If m′=m/2, then the two vertical sections are of equal width. For engineering or other reasons, one vertical section may be wider than the other within the bounds of this invention. In one embodiment, the display comprises four vertical sections, of which the present example shows a left half. While the example emphasizes one pixel drive circuit at coordinate (x, y) it is understood that pixel drive circuits at all coordinates must operate as the example does in order for the solution to be a general one.

The calculations for this example are an extension of those developed for FIG. 7B. The differences are in the presence on the word line of an extended section underneath a vertical section wherein the word line does not interact with the pixel circuits above it and a similarly long section caused by the display controller for that vertical section needing to reach the left edge of the display. The latter is required since the area comprising the array of pixel drive circuits must be continuous and cannot have gaps in it to accommodate other types of circuitry.

The general approach in this embodiment is to make the time required for the word line high signal to propagate from the word line driver at coordinate (0, y) to the target pixel at coordinates (x, y) equal to the time required for the bit line trigger signal to propagate from the circuit near coordinates (0, 0) to the bit line driver at coordinate (x, 0). A second part of the current approach is to make the time required for the word line trigger signal to propagate from the circuit near coordinates (0, 0) to the row decoder and word line select circuit at coordinate (0, y) substantially equal to the time required for the complementary bit line data to propagate up complementary bit lines 443 to the target pixel at coordinates (x, y).

Signals in FIG. 7C are started from a circuit near coordinate (0, 0) in the lower left corner of array 340 in one embodiment. The coordinates may should be considered as represent the rows and column of array 340.

Signal TR₁ represents the propagation time for a word line trigger signal. A word line trigger signal requiring time TR₁ to propagate originates in a circuit positioned near coordinate (0, 0) and is delivered to an AND gate (not shown) in the row decoder and word line circuit for each row. The second input to the AND gate is the signal from the row decoder circuit of the row select circuitry. Since only one row is selected, only one AND gate has its logic satisfied and holds the word line for that row high.

In one embodiment, the AND gate is not used and a tri-state buffer is used in its place. A tristate buffer has one input, which is the data from the word line decoder, and an enable signal, which in this case is the row decoder and word line trigger signal. Before the word line trigger signal is asserted on the enable terminal, the output of the tri-state buffer floats. Afterwards, the driver for the rows not selected are low and the drive for the selected row is high. This performs somewhat the same function logically as the AND gate but does not continuously drive the on state word line.

Once the word line driver output is pulled high, the word line signal propagates down word line 444 beginning at coordinate (0, y). The first segment requires time TR₄ to propagate across vertical section 441 of array 440. Wordline 444 does not interact with any of the pixel drive circuits of vertical section 441 but wordline 344 does interact with all of the pixel drive circuits of vertical section 442, thereby creating a condition where the RC characteristic of the part of word line 444 with vertical section 441 is different to the RC characteristic of the part of word line 444 within vertical section 442. It is estimated that the capacitance of the section within vertical section 441 is lower than the capacitance of the section of word line 444 within vertical section 442, although this is less important than the possibility that the RC time constant in the two vertical sections may be different. The portion of word line 344 within vertical 342 actually extends to coordinate (m, y). The termination at coordinate (x, Y) is to facilitate the remainder of the discussion regarding propagation delay.

The total time T_{TOT_WLINE} required for a word line signal to reach coordinate (x, y). The components are the time TR₁ required for the word line trigger signal to reach the selected row, TR₃ for the time required to satisfy the AND gate logic, TR₄ for the propagation time across vertical section 341, and TR₂ for the time required to reach coordinate (x, y) within vertical 342. This may be stated in closed form as T_{TOT_WLINE}=TR₁+TR₂+TR₃+TR₄

Releasing the bit line data onto the complementary bit lines for delivery to pixels on a selected row creates a second timing issue that must be taken into account. The bit line trigger signal originates in a circuit near coordinate (0, 0) and propagates to a bit line driver (not shown) at coordinate (x, 0). Bit line data is loaded onto complementary bit lines in response to the receipt of the bit line trigger signal. The complementary data propagates on bit lines 443 to coordinate (x, y) where it can be loaded onto the SRAM memory cell located at that coordinate.

In one embodiment, the output of a bit line memory data cell is asserted on a tri-state buffer. A tristate buffer has one data input, which is the pixel data from the bit line memory cell, and an enable signal in the form of a bit line trigger signal. Before the bit line trigger signal is asserted on the enable terminal, the output of the tri-state buffer floats. This effectively prevents the new bit line data from encountering a word line that is still high from the previous row write sequence. All bit line drivers in all of the various embodiments of this disclosure may operate in this manner.

In order for the bit line trigger signal propagation delays TB₄ and TB₁ to match the propagation delays TR₄ and TR₂ on word line 444, it must match the RC time constant for the section of word line 344 that passes under vertical section 441 and the RC time constant for the section of word line 344 that passes under vertical section 442. In other words, TR₄=TB₄ and TR₂=TB₁ as close as possible.

Word line 444 propagation time TR₄ through vertical section 341 is invariant since all pixel drive circuits responsive to word line 344 lie within vertical section 342 and all signals directed to pixel drive circuits in vertical section 342 must transit vertical section 341. As a result, bit line trigger signal propagation time in a region parallel to vertical section 341 should be invariant as well. In one embodiment, TR₄ TB₄ and in fact TR₄>TB₄. The inequality may result from using a direct line not parallel to vertical section 341. Additional delay elements located elsewhere may compensate for the inequality in that case.

The portion of word line 444 that serves the pixel drive circuits of vertical section 442 does interact with all the pixel drive circuits found along row y associated with coordinates (x, y). The time TR₂ required for the word line signal to propagate to coordinate (x, y) from coordinate (m′, y), the point at which it enters vertical section 442, should be the same as time TB1, the time required for the bit line trigger signal to propagate from a point adjacent to coordinate (m′, 0) to coordinate (x, 0), the location of the bit line driver. Circumstances under which a shortened bit line driver trigger circuit delivers a trigger signal along a trigger circuit parallel to a part, but not all, of the lower base of vertical section 441 is conceived and can be accommodated by compensating delays generated by other circuits.

The most efficient way to match propagation delay is to match the RC characteristics and the length of word line 444 on the bit line trigger signal line. Applicant notes that using same type circuit in both locations will result in a similar RC characteristic provided the capacitances on the two circuits remain substantially the same. In the case of word line 444, the design requirements of the word line are dictated by the design whereas the design requirements of the bit line trigger circuit used to deliver the bit line signal are more flexible. By designing in the use of a circuit similar to the word line to deliver the bit line trigger signal to the bit line driver, the propagation characteristics of the two circuits should be substantially alike. The regular geometry of the array of pixel drive circuits supports that implementation.

In the case of the propagation of the complementary bit line data on the bit line, a similar approach can be taken with respect to the propagation of the word line trigger signal. The structure of the complementary bit lines 443 is determined by the data requirements for the SRAM memory cell and by the pitch of the pixel drive circuits. Again it is possible to use an identical structure to deliver the word line release signal to the row decoder and word line drive circuits. This case is simpler because bit line circuits 443 only propagate through active pixel drive circuits and has the potential to interact with a pixel circuit on any row, although it will in a given instance only interact with the one for which the word line signal is high.

The embodiments of the present invention described herein enable the development of a large scale array of pixels based on memory elements with a predictable delay from the initiation of writing of a pixel to the writing of the pixel for both bitlines and wordlines by using design techniques to reduce time discrepancies between the time of arrival of the rising wordline and the time of arrive of data to be written on the bitlines. The design techniques described herein, when implemented, will result in accurate time tracking to all pixels of the array and not to just a small subset in one location.

Other applications of the design techniques described herein are conceived within the present invention.

1. A backplane forming part of a display system operative to drive an array of pixel drive circuits, the backplane comprising a plurality of rows and a plurality of columns of pixel drive circuits, wherein each pixel drive circuit comprises a memory circuit operative to hold a bit of image data and each pixel drive circuit operative to apply a drive waveform responsive to the image data state of the memory circuit, and wherein
the backplane further comprises at least one row decoder for each row of the array of pixel drive circuits wherein each row decoder is operative to drive a single word line circuit arrayed on a single row segment to select the memory circuits of the pixel drive circuits to receive data over bit lines, and wherein the number of row segments for each row equals the number of row decoders for each row, and wherein
the set of row decoder circuits comprises at least one row decoder circuit for each row of pixel drive circuits is arrayed along a side of the array of pixel drive circuits, and wherein a row decoder control circuit located near the row decoder circuits and in proximity to a bottom row of the array of pixel drive circuits releases signals to the row decoder circuits that determine which row is selected to receive data, and wherein
a row decoder circuit, upon detecting that it is selected, passes a signal to a word line driver to enable its word line to be driven to a state wherein the memory circuits of the row segment that are connected to the word line are placed in a state to receive data from the column drivers over bit lines, and wherein
the data to be loaded onto the pixels of the row to be selected by the word line are placed on memory circuits, each forming part of a column driver circuit of a set of column driver circuits, by data handling circuits, and wherein
a column driver control circuit located near the same corner of the array of pixel drive circuits at which the row decoder control circuit sends a signal to a logic circuit to assert the values on the memory circuits of the column drivers onto the bit lines, and wherein
the circuit over which the column driver control circuit sends signals to assert the values on the memory circuits of the column drive circuits on the bit lines is substantially RC matched to and substantially coextensive with, the word line circuits of the array of pixel drive circuits, such that the propagation delays of the two circuits are substantially matched over any selected similar distance on the two circuits.

2. The backplane of claim 1, wherein the circuit over which the column driver control circuit sends trigger signals to the column driver circuits matches the layout of the selected word line circuit and at least one adjacent non-selected word line circuit.

3. The backplane of claim 2, wherein the word line driver circuit comprises a memory circuit, an optional level shifter, a bistable logic circuit operative to receive an input from the level shifter and to receive a second input from a trigger signal circuit and operative to assert an output to an associated word line.

4. The backplane of claim 3, wherein the trigger signal circuit over which the column driver control circuit sends trigger signals to the column driver circuits, comprises a series of conductor circuits that each tap the circuit over which the trigger signal is asserted and delivers those signals to the second inputs of a plurality of bistable logic circuits, and wherein the conductor circuits are substantially parallel to the circuit over which the column driver control circuit sends trigger signals with propagation in the same direction.

5. The backplane of claim 4, wherein each of the conductor circuits that tap the circuit over which the trigger signal is sent comprises a sample circuit positioned between the tap point on the circuit on which the trigger signal is asserted and the series of points on the conductor circuit at which it connects to the second input of the bistable logic circuits, wherein the sample circuit comprises a rising edge detector circuit element and an output circuit operative to hold its output high for a period of time sufficient to enable the column driver circuit to assert its output on a bit line and short enough to insure the bistable logic circuit does not have a signal present on its second input when the next data is written to the memory circuit of the column driver.

6. The backplane of claim 1, where the word line driver circuit operative to control the word line for a single row segment comprises a logic circuit operative to release a signal when two valid inputs are received, an optional voltage level shifter and an optional isolating inverter circuit, and wherein the two inputs to the logic circuit are a signal from the row decoder circuit for the row and a release signal received over a conductor from a release timing circuit, thereby enabling the output of the selected row to place the word line controlled by the word line driver circuit to be placed in state so that the memory circuits of the pixel circuit drivers attached to that word line are placed in a state to receive data asserted over bit lines from a group of column drivers associated with those bit lines.

7. The backplane of claim 6, wherein the logic circuit comprises one of an AND gate, a level sensitive D flip-flop, or an edge sensitive D latch.

8. The backplane of claim 6, wherein the conductor from the release timing circuit for the word line drivers comprises a main conductor and a plurality of shorter parallel conductors that connect to the main conductor at periodic tap points at which the shorter conductors connect to the main conductor and to an input to a subset of the logic circuits comprising at least a plurality, each forming a part of a word line driver circuit, and wherein the shorter conductors are substantially parallel to the main conductor and have the currents thereon flow in substantially the same direction as the direction of the current on the main conductor.

9. The backplane of claim 7, wherein each of the plurality of shorter parallel conductors comprises a sample circuit positioned between the tap point on the main conductor and the inputs to the subset of the logic circuits.

10. The backplane of claim 6, wherein the conductor over which the release signal is received is a bit line of at least one column of dummy pixel drive circuits substantially identical to the active pixel driver circuits and bit lines of the active array, and wherein the release signal to a dummy column driver circuit is controlled and generated by a control circuit that is operative to assert a timing release signal on the memory circuit of a dummy column driver circuit substantially identical to the active column driver circuit and wherein the memory circuit is set to a data state such that the signal propagating on the conductor is configured to satisfy the input requirements of the logic circuit for release of its signal.

11. The backplane of claim 10, wherein the memory circuit of the dummy column driver is configured such that the memory circuit is always in an ON state such that, when the release signal is received at the dummy column driver circuit from the control circuit, the conductor receives the release signal to be delivered to one input of each of the logic circuits of the associated word line driver circuits.

12. The backplane of claim 1, wherein the backplane that comprises at least one row decoder circuit for each row of the array of pixel drive circuits comprises at least two row decoder circuits for each row of the array of pixel drive circuits wherein each row decoder circuit is operative to drive a single word line circuit segment arrayed on a section of a single row to select the memory circuits of the pixel drive circuits of that section operated by the word line to receive data over bit lines, and wherein
each row of the array of pixel drive circuits comprises a like number of pixel drive circuits, and wherein the rows of the array of pixel drive circuits are divided vertically into non-overlapping sections with distinct vertical boundaries, the number of vertical sections corresponding to the number of row decoder circuits, and wherein all pixel drive circuits of all rows are located in one and only one section, wherein all the pixel drive circuits of each row segment within each section are each operated by a single word line driver controlled by a single row decoder circuit, and wherein
each row is controlled by the same number of row decoder circuits in the same positions relative to an edge of the array of pixel drive circuits, and wherein a first of the at least two row decoders for each row of the array of pixel drive circuits is positioned in proximity to an edge of the array of pixel drive circuits, and wherein the second of the at least two row decoder circuits for each row of the array of pixel drive circuits is positioned in proximity to the first of the at least two row decoder circuits with the first of at least two row decoder circuits between the second of at least two row decoder circuits and the edge of the array of pixel drive circuits, and wherein each of the at least two row decoders for each row connects to a word line for a different segment of that row through an intervening word line driver, and wherein
the first of the at least two row decoder circuits positioned near to an edge of the array of pixel drive circuits controls a word line operative to control the memory circuits of an associated row of the first vertical section of the array of pixel drive circuits and wherein the second of the at least two row decoder circuits positioned near the first of the at least two row decoder circuits positioned near the edge of the array of pixel drive circuits controls a second word line operative to control the memory circuits of a row of the second vertical section of the array of pixel drive circuits, and wherein one of the first and second vertical sections of the array of pixel drive circuits is adjacent to the edge of the array of pixel drive circuits and the other of the first and second vertical sections of the array of pixel drive circuits is adjacent to the opposite edge of the other vertical section of pixel drive circuits, and wherein
the word lines for the rows of the vertical section of the array of pixel drive circuits adjacent to the edge of the array of pixel drive circuits controls state of the memory circuits of that vertical section and wherein the word lines for the rows of the vertical section of the array of pixel drive circuits adjacent to the opposite edge of the vertical section of the array of pixel drive circuits adjacent to the edge of the array of pixel drive circuits each comprise a first word line segment that passes through the first vertical section without interacting with the memory circuits of the pixel drive circuits thereof and a second word line segment electrically connected to the non-interacting first word line segment that passes through the second vertical section and controls the state of the memory circuits of the pixel drive circuits thereof, and wherein
a separate row decoder control circuit is present for each set of row decoder circuits operative to control the state of the memory circuits of the rows of one of the vertical sections of pixel drive circuits, and wherein each separate row decoder circuit receives a signal from the row decoder control circuit for that set of row decoder circuits, which signal determines which row is selected for data to be written to the memory circuits of the pixel drive circuits of that row that are controlled by the word line control circuit by the word line driver controlled by the row decoder circuit, and wherein
each row decoder circuit, upon detecting that it is selected, passes a signal to its associated word line driver to enable the associated word line segment to be driven to a state wherein the memory circuits that are connected to that word line segment are placed in a state to receives data over bit lines, and wherein
the data to be loaded onto the pixel driver circuits of the row segment to be selected by the word line are loaded on memory circuits, each forming part of a column driver circuit of a set of column driver circuits, by data handling circuits, and wherein
a column driver control circuit is located near the bottom of the array of pixel drive circuits in a corner position to be able to deliver a release signal to logic circuit that enables the column drive circuits to assert the data values on the memory circuits of the column drivers onto the bit lines, and wherein
the circuit over which each column driver control circuit sends signals to its associated column driver circuits to assert the values on the memory circuits of the column driver circuits onto the bit lines is substantially RC matched to the word line circuits of the array of pixel drive circuits of the array of pixel drive circuits, such that the propagation delays of the two circuits are substantially matched over any selected distance.

13. The backplane of claim 12, wherein the circuits over which each of the column driver control circuits sends a trigger signal to their respective column driver circuits matches the layout of the selected word lines for the respective word line circuits associated with the same section of the array of pixel drive circuits.

14. The backplane of claim 13, wherein each of the word line driver circuits comprises a memory circuit, an optional level shifter or alternatively a conductor, a bistable logic circuit operative to receive an input from the optional level shifter or conductor and to receive a second input from a trigger signal circuit and operative to assert an output onto one of a plurality of inverter circuits in series.

15. The backplane of claim 12, wherein each word line driver circuit operative to control the word line for a segment of a single row comprises a logic circuit operative to release a signal when two valid inputs are received, an optional voltage level shifter or direct conductor, and an optional isolating inverter circuit, and wherein the two inputs to the logic circuit are a signal from the row decoder circuit for the row and a release signal received over a conductor from a release timing circuit, thereby enabling the output of the selected word line driver circuit to place the word line controlled by the word line driver circuit in a state such that the memory circuits of the pixel driver circuits attached to those word lines to receive data asserted over bit lines from the group of column drivers associated with those bit lines.

16. The backplane of claim 15, wherein the logic circuit comprises one of an AND gate, a D flip-flop circuit that responds to signal levels, or a D latch that responds to the edges of the signals applied to it.

17. The backplane of claim 1, wherein the word line high signal operates at a lower voltage than the upper supply voltage for the array of pixel drive circuits.
